(19) United States
(12) Patent Application Publication
(10) Pub. No.: US 2019/0339227 A1
(43) Pub. Date: Nov. 7, 2019

(54) ROOM TEMPERATURE HYDROGEN GAS SENSOR

(71) Applicant: KING FAHD UNIVERSITY OF PETROLEUM AND MINERALS, Dhahran (SA)

(72) Inventors: Qasem Ahmed DRMOSH, Dhahran (SA); Zain Hassan YAMANI, Dhahran (SA); Amar Kamal MOHAMEDKHAIR, Dhahran (SA); Abdulmajeed Hasan HENDI, Dhahran (SA)

(73) Assignee: KING FAHD UNIVERSITY OF PETROLEUM AND MINERALS, Dhahran (SA)

(21) Appl. No.: 15/970,575

(22) Filed: May 3, 2018

(51) Int. Cl. G01N 27/414; G01N 27/416; G01N 27/333; C23C 14/08; C23C 14/34; C23C 14/16; C01G 55/00; C01G 19/02

(52) U.S. Cl. CPC G01N 27/4141; G01N 27/4162; G01N 27/333; C23C 14/086; C01P 2004/64; C23C 14/16; C01G 55/00; C01G 19/02; C23C 14/34

(57) ABSTRACT

A room temperature hydrogen gas sensor comprising tin(IV) oxide and platinum layered on an electrode substrate is described. The tin(IV) oxide may be polycrystalline with an average layer thickness of 10-700 nm, and topped with platinum having an average layer thickness of 1-15 nm. The room temperature hydrogen gas sensor may be used to detect and measure levels of H₂ gas at room temperature and at concentrations of 50-1800 ppm, with fast response and high stability. A method of making the room temperature hydrogen gas sensor is also described, and involves sputtering to deposit tin(IV) oxide and platinum on a substrate, which is then subjected to low-temperature annealing step.

### BACKGROUND OF THE INVENTION

### Technical Field

The present invention relates to a room temperature hydrogen gas sensor comprising a polycrystalline SnO₂ layer and a thin Pt layer.

### Description of the Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Nowadays, there is a considerable interest in developing reliable hydrogen (H₂) sensors capable of detecting ppm level concentrations with a high sensitivity and a quick response time. This interest is due to the need for detecting trace amounts of H₂ leaking from proton-exchange membranes, power generators, automobiles, and long-term storage devices. See G. Mousa, F. Golnaraghi, J. D. Vaal, and A. Young. Detecting proton exchange membrane fuel cell hydrogen leak using electrochemical impedance spectroscopy method. Journal of Power Sources 246 (2014)110-16, incorporated herein by reference in its entirety. Room temperature (RT) H₂ sensors have attracted much interest because of their ability to work safely in an inflammable environment and with an extremely low power consumption. So far, several H₂ gas sensors have been developed, such as metal oxide sensors, surface acoustic wave sensors, and optical fiber-based sensors. See H. Gu, Z. Wang, and Y. Hu. Hydrogen gas sensors based on semiconductor oxide nanostructures. Sensors 12 (2012) 5517-50; T. Hübert, L. Boon-Brett, G. Black, U. Banach. Hydrogen sensors—A review. Sensors and Actuators B 157 (2011) 329-352; and M. Yang and J. Dai. Fiber Optic hydrogen sensors: a review. Photonic Sensors 4 (2014) 300-24, each incorporated herein by reference in their entirety. Amongst them, metal oxide semiconductor based sensors such as SnO₂ and ZnO are the most commonly used sensors due to their natural non-stoichiometry characteristics, which allow the adsorption of ambient oxygen onto their surfaces, and make them sensitive to different flammable, combustible, and pollutant gases. See J. Chu, X. Peng, Z. Wang, P. Feng. Sensing performances of ZnO nanostructures grown under different oxygen pressures to hydrogen. Materials Research Bulletin 47 (2012) 4420-4426, incorporated herein by reference in its entirety. The fundamental operating principle of these types of sensors is based on a variation in electrical resistance upon H₂ adsorption/desorption on their surfaces. In a successful chemical gas sensor, the variation in resistivity before and after introducing the test gas must be great, rapid, and proportional to the gas concentration.

SnO₂ is an n-type semiconductor and has attracted much interest for H₂ detection due to its good sensitivity at high operating temperatures, and good thermal and mechanical stability. See C. Jiang, G. Zhang, Y. Wu, L. Li and K. Shi. Facile synthesis of SnO₂ nanocrystalline tubes by electrospinning and their fast response and high sensitivity to NO, at room temperature. Cryst Eng Comm 14 (2012) 2739-47, incorporated herein by reference in its entirety. Numerous studies have been reported on the fabrication of high sensitivity SnO₂ nanorods, nanowires, and nanoparticles for H₂ sensors. See Y. Shen, X. Cao, B. Zhang, D. Wei, J. Ma, W. Liu, C. Han, Y. Shen. Synthesis of SnO₂ nanorods and application to H₂ sensor. Journal of Alloys and Compounds 593 (2014) 271-74; E. M. El-Maghraby, A. Qurashi, and T. Yamazaki. Synthesis of SnO₂ nanowires their structural and H₂ gas sensing properties. Ceramics International 39 (2013) 8475-80; and Y. Shen, W. Wang, A. Fan, D. Wei, W. Liu, C. Han, Y. Shen, and D. Meng, X. San. Highly sensitive hydrogen sensors based on SnO₂ nanomaterials with different morphologies. International Journal of Hydrogen Energy 40 (2015) 15773-79; each incorporated herein by reference in their entirety. However, such sensors are still under development and they are inappropriate for commercialization due to their limited preparation methods toward mass production. See N. V. Toan, N. V. Chien, N. V. Duy, H. S. Hong, H. Nguyen, and N. V. Hieu. Fabrication of highly sensitive and selective H₂ gas sensor based on SnO₂ thin film sensitized with microsized Pd islands. Journal of Hazardous Materials 301 (2016) 433-42, incorporated herein by reference in its entirety. SnO₂ in the form of a thin film is promising for gas sensing due to its simple design and scalable fabrication for commercialization. SnO₂ thin films for H₂ detection were fabricated by a variety of methods, including sputtering, chemical vapor deposition, thermal evaporation, and sol-gel technique See N. V. Duy, T. H. Toanb, N. D. Hoa, and N. V. Hieu. Effects of gamma irradiation on hydrogen gas-sensing characteristics of Pd—SnO₂ thin film sensors. International Journal of Hydrogen Energy 40 (2015)12572-80; S. Vallejos, F. Maggio, T. Shujah and C. Blackman. Chemical vapour deposition of gas sensitive metal oxides. Chemosensors 4 (2016)1-18; A. Amutha, S. Amirthapandian, B. Sundaravel, A. K. Prasad, B. K. Panigrahi, and P. Thangadurai. Structural and gas sensing properties of ex-situ oxidized Sn grown by thermal evaporation. Applied Surface Science 360 (2016) 731-37; and S. Shukla, S. Patil, S. C. Kuiry, Z. Rahman, T. Du, L. Ludwig, and C. Parish, S. Seal. Synthesis and characterization of sol-gel derived nanocrystalline tin oxide thin film as hydrogen sensor. Sensors and Actuators B 96 (2003) 343-53, each incorporated herein by reference in their entirety.

Unfortunately, SnO₂ thin films still have some drawbacks such as low sensitivity at low concentrations, poor selectivity, and a requirement for high operating temperatures. See K. Lee, Y. Chiang, Y. Lin, and F. Pan. Effects of PdO decoration on the sensing behavior of SnO₂ toward carbon monoxide. Sensors and Actuators B: Chemical 226 (2016) 457-64; and S. Rane, S. Arbuj, S. Rane, and S. Gosavi. Hydrogen sensing characteristics of Pt—SnO₂ nano-structured composite thin films. J Mater Sci: Mater Electron 26 (2015) 3707-16, each incorporated herein by reference in their entirety. Such deficiencies require further advancement of research to obtain a high performance RT (room temperature) H₂ sensor. Four different strategies are usually used to rectify the above issues in order to enhance the H₂ gas sensing: (I) doping SnO₂ films with appropriate elements, (II) decoration of metal nanoparticles over SnO₂ films, (III) employment of hybrid SnO₂ thin films/metal oxide heterostructures, and (IV) illumination of the SnO₂ surface by UV light. A common approach to improve the gas sensing performance for H₂ detection is sensitizing the fabricated SnO₂ films by doping or decorating with noble metals such as Pt, Au, or Pd. The role of catalytic noble metals is to increase the dissociation efficiency of oxygen and H₂ molecules to more reactive atomic forms. See B. Sam Kang, H. Wang, L. Tien, F. Ren, B. P. Gila, D. P. Norton, C. R. Abernathy, J. Lin and S. J. Pearton. Wide bandgap semiconductor nanorod and thin film gas sensors. Sensors 6 (2006) 643-66, incorporated herein by reference in its entirety. Recently, Nguyen et al. have shown that high sensitivity H₂ sensors operating at relatively high temperatures ranging from 200° C. to 400° C. can be achieved when micro-sized Pd islands prepared by sputtering technique are deposited onto the surface of the sputtered SnO₂ films. See N. V. Toan et al., incorporated herein by reference in its entirety. Sapana et al. investigated the effect of the Pt addition on SnO₂ films fabricated via spin coating technique. See S. Rane et al., incorporated herein by reference in its entirety. According to their study, the gas sensing performance of Pt—SnO₂ composite based H₂ sensors operating at 85° C. exhibited a better response compared to the pure SnO₂ thin films.

Post-deposition thermal annealing of the as-deposited sputtered SnO₂ films has also emerged as an effective strategy to enhance the gas sensing performance. D. Kim et al. reported that the SnO₂ sensors prepared by RF magnetron sputtering, where the films are subjected to post heat-treatment at 650° C. in air, showed a 10% to 20% higher response than the as-fabricated ones. See H. Aim, J. H. Noh, S. Kim, and R. A. Overfelt, Y. Yoon, D. Kim. Effect of annealing and argon-to-oxygen ratio on sputtered SnO₂ thin film sensor for ethylene gas detection. Materials Chemistry and Physics 124 (2010) 563-68, incorporated herein by reference in its entirety.

On the other hand, it has been reported that annealing SnO₂ thin films at temperatures higher than 600° C. can give rise to thermal stress owing to the mismatch of thermal expansion characteristics between the substrate and the SnO₂ film. See Z. Tang, P. Chang, R. Sharma, G. Yan, I. Hsing, J. Sin. Investigation and control of microcracks in tin oxide gas sensing thin-films. Sensors and Actuators B 79 (2011) 39-47, incorporated herein by reference in its entirety. After annealing, this mismatch is accompanied by anisotropic contraction as the substrate and film cools, resulting in the formation of cracks at the SnO₂ films which, in turn, affect the gas sensing properties of the film. Hence, proper post-annealing treatment of SnO₂ film along with some additives like noble metals are desirable to augment the gas sensing performance at RT.

In view of the foregoing, one objective of the present invention is to provide a room temperature hydrogen gas sensor, a method of making, and a method of using to detect hydrogen gas concentrations through changes in conductivity.

### BRIEF SUMMARY OF THE INVENTION

According to a first aspect, the present disclosure relates to a room temperature hydrogen gas sensor. The room temperature hydrogen gas sensor comprises at least two electrodes on a substrate, the electrodes separated by 10-500 μm; a SnO₂ layer in contact with the at least two planar electrodes on the substrate, the SnO₂ layer having an average thickness of 10-700 nm; and a platinum layer in contact with the SnO₂ layer, the platinum layer having an average thickness of 1-15 nm.

In one embodiment, the SnO₂ layer consists essentially of SnO₂, and the Pt layer consists essentially of Pt.

In one embodiment, the at least two electrodes are substantially planar.

In one embodiment, the platinum layer has an RMS surface roughness of 0.1-4 nm.

In one embodiment, the substrate comprises silica.

In a further embodiment, where the substrate comprises silica, the room temperature hydrogen gas sensor has a transmittance of 30-50% for a wavelength in a range of 420-500 nm.

In one embodiment, the SnO₂ layer comprises polycrystalline SnO₂ having an average grain size of 5-20 nm.

According to a second aspect, the present disclosure relates to a method of making the room temperature hydrogen gas sensor of the first aspect. This method involves the steps of sputtering SnO₂ onto the at least two electrodes on the substrate to produce an amorphous SnO₂ layer, sputtering platinum onto the amorphous SnO₂ layer to produce a deposited platinum layer, and annealing the amorphous SnO₂ layer and the deposited platinum layer at 130-250° C.

In one embodiment, the annealing is at 140-170° C. for 1-5 hours.

In one embodiment, the SnO₂ is sputtered by a RF sputtering mode, and the Pt is sputtered by a DC sputtering mode.

According to a third aspect, the present disclosure relates to a method of using the room temperature hydrogen gas sensor of the first aspect. This method involves contacting the platinum layer with a first gas sample comprising hydrogen gas, and measuring a first resistivity across the at least two electrodes. Here, the first resistivity is decreased by 70-99.9% relative to a second resistivity arising from a second gas sample, where the second gas sample is substantially free of hydrogen gas.

In one embodiment, the first gas sample comprises 50-1800 ppm hydrogen gas.

In one embodiment, the first gas sample has a temperature of 0-50° C. and a pressure of 0.9-1.1 atm.

In one embodiment, the first gas sample has a temperature of 20-35° C.

In one embodiment, the second gas sample comprises 300-5,000 ppm of at least one gas selected from the group consisting of NH₃, n-butane, O₂, CO₂, and N₂.

In one embodiment, the decrease in the first resistivity has a response time of 0.5-100 s.

In one embodiment, the second gas sample comprises 0.1-99 vol % of at least one gas selected from the group consisting of O₂, CO₂, H₂O, Ar, and N₂, relative to a total volume of the second gas sample, or consists essentially of O₂, CO₂, H₂O, Ar, and/or N₂.

In one embodiment, the decrease in the first resistivity has a recovery time of 200-400 s.

In one embodiment, the room temperature hydrogen gas sensor is in contact with 500-5,000 ppm H₂ gas for 1-6 months before the contacting with the first gas sample.

In one embodiment, the method has a repeatability of at least 99%.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 shows an experimental setup used for testing a room temperature hydrogen gas sensor.

FIG. 2 shows XRD (X-Ray Diffraction) patterns of samples S1-S6.

FIG. 3A shows 3D, 2D, and linear AFM surface profiles and calculated RMS surface roughness of the S1 sample.

FIG. 3B shows 3D, 2D, and lincar AFM surface profiles and calculated RMS surface roughness of the S2 sample.

FIG. 3C shows 3D, 2D, and linear AFM surface profiles and calculated RMS surface roughness of the S6 sample.

FIG. 4 shows UV-Vis transmittance spectra of samples S1-S6.

FIG. 5A is an XPS (X-Ray Photoelectron Spectroscopy) survey spectrum of the S3 sample.

FIG. 5B is a representative resolved Sn 3d XPS spectrum of the S3 sample.

FIG. 5C is a representative deconvoluted Pt 4fXPS spectrum of the S3 sample.

FIG. 5D is a representative resolved O1s XPS spectrum of the S3 sample.

FIG. 6A shows the resistance of sample S1 over time while being exposed to increasing concentrations of H₂ gas (250 to 1750 ppm) at room temperature.

FIG. 6B shows the resistance of sample S3 over time while being exposed to increasing concentrations of H₂ gas (250 to 1750 ppm) at room temperature

FIG. 7 shows the response obtained from samples S1-S6 at different concentrations of H₂ gas at room temperature.

FIG. 8 is a repeatability test of sample S3 with 1000 ppm H₂ gas at room temperature.

FIG. 9 is a plot of both response time and recovery time of sample S3 at different H₂ concentrations at room temperature.

FIG. 10 displays the response of sample S3 exposed at RT to different concentrations (750, 1250, 1750 ppm) of H₂ gas.

FIG. 11 shows the response of sample S3 in the presence of 1250 or 1750 ppm H₂ gas over a temperature range of RT to 500° C.

FIG. 12 shows the response of sample S3 in the presence of different gases at RT.

### DETAILED DESCRIPTION OF THE EMBODIMENTS

Embodiments of the present disclosure will now be described more fully hereinafter with reference to the accompanying drawings, in which some, but not all embodiments of the disclosure are shown.

The present disclosure will be better understood with reference to the following definitions. As used herein, the words “a” and “an” and the like carry the meaning of“one or more.” Within the description of this disclosure, where a numerical limit or range is stated, the endpoints are included unless stated otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the words “about,” “approximately,” or “substantially similar” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), +/−15% of the stated value (or range of values), or +/−20% of the stated value (or range of values). Within the description of this disclosure, where a numerical limit or range is stated, the endpoints are included unless stated otherwise. Also, all values and subranges within a numerical limit or range are specifically included as if explicitly written out.

As used herein, “compound” is intended to refer to a chemical entity, whether as a solid, liquid, or gas, and whether in a crude mixture or isolated and purified.

As used herein, “composite” refers to a combination of two or more distinct constituent materials into one. The individual components, on an atomic level, remain separate and distinct within the finished structure. The materials may have different physical or chemical properties, that when combined, produce a material with characteristics different from the original components. In some embodiments, a composite may have at least two constituent materials that comprise the same empirical formula but are distinguished by different densities, crystal phases, or a lack of a crystal phase (i.e. an amorphous phase).

The present disclosure is intended to include all hydration states of a given compound or formula, unless otherwise noted or when heating a material. For example, Ni(NO₃)₂ includes anhydrous Ni(NO₃)₂, Ni(NO₃)₂.6H₂O, and any other hydrated forms or mixtures. CuCl₂ includes both anhydrous CuCl₂ and CuCl₂.2H₂O.

In addition, the present disclosure is intended to include all isotopes of atoms occurring in the present compounds and complexes. Isotopes include those atoms having the same atomic number but different mass numbers. By way of general example, and without limitation, isotopes of hydrogen include deuterium and tritium. Isotopes of carbon include ¹³C and ¹⁴C. Isotopes of oxygen include ¹⁶O, ¹⁷O, and ¹⁸O. Isotopes of tin include ¹¹²Sn, ¹¹⁴⁻¹²⁰Sn, ¹²²Sn, and ¹²⁴Sn. Isotopes of platinum include ¹⁹⁰Pt, ¹⁹²Pt, ¹⁹⁴pt, ¹⁹⁵Pt, ¹⁹⁶pt, and ¹⁹⁸Pt. Isotopically-labeled compounds of the disclosure may generally be prepared by conventional techniques known to those skilled in the art or by processes analogous to those described herein, using an appropriate isotopically-labeled reagent in place of the non-labeled reagent otherwise employed.

According to a first aspect, the present disclosure relates to a room temperature hydrogen gas sensor. The room temperature hydrogen gas sensor comprises at least two electrodes on a substrate, a SnO₂ layer in contact with the at least two planar electrodes on the substrate, and a platinum layer in contact with the SnO₂ layer.

As described here, “room temperature” may refer to a temperature in a range of 18-24° C., preferably 20-22° C., or about 20° C., or about 25° C. However, in certain cases, and depending on weather, air conditioning, heating, ventilation, and personal preferences, “room temperature” may refer to a temperature lower than 18° C., for example, 15 or 16° C., or to a temperature greater than 24° C., for instance, 27° C. In one embodiment, “room temperature” may refer to more than one temperature in one of the ranges as described previously. For instance, a “room temperature” gas sensor may have a temperature of 20° C., while coming in contact with a “room temperature” gas having a temperature of 22° C. A small difference in temperatures may arise from the gas sensor being attached to a housing, casing, wall, or some other object that has a heat sink effect or a higher heat capacity. In another aspect, the term “room temperature” refers to the ambient temperature of a sample or environment that is in contact with the gas sensor.

In one embodiment, the substrate may be planar, and may have a rectangular shape, a circular shape, or some other shape. In one embodiment, the substrate may have a planar side with a surface area of 0.1-100 cm², preferably 0.25-50 cm², more preferably 0.5-10 cm², even more preferably 0.7-8 cm². However, in some embodiments, the substrate may have a planar side with a surface area smaller than 0.1 cm² or larger than 100 cm². The substrate may have a thickness of 0.10-20 mm, preferably 0.15-15 mm, more preferably 0.17-10 mm, however, in some embodiments, the substrate may have a thickness of less than 0.10 mm, or greater than 20 mm. In an alternative embodiment, the substrate may be curved, grooved, knurled, or shaped into some other non-planar arrangement.

The substrate may be a sapphire substrate, a quartz substrate, a magnesium oxide single crystal substrate, a ceramic substrate, an alumina substrate, a silicon substrate (e.g. silicon wafer or silicon oxide), a silicon nitride substrate, or some other substrate. In one embodiment, the substrate comprises silica (SiO₂), and preferably in one embodiment, the substrate consists essentially of silica, meaning that at least 98 wt %, preferably 99 wt %, more preferably at least 99.9 wt % of the substrate is silica, relative to a total weight of the substrate. The silica may be amorphous silica, fumed silica, quartz, or some other type of silica. In alternative embodiments, the substrate may be a type of glass such as flint glass, soda lime glass, or borosilicate glass. In one embodiment, the substrate may be a glass coverslip or a glass slide for a microscope. In an alternative embodiment, the substrate may not necessarily be silica, but may be some other substance having a low electrical conductivity and/or considered an electrical insulator. Defined here, an insulator refers to a solid material with a high electrical resistivity that may prevent an electric current from flowing between two points. The electrical resistivity of the insulator may be at least 10² Ω·m, preferably at least 10³ Ω·m, more preferably at least 10⁴ Ω·-m at 20° C.

In one embodiment, the at least two electrodes may be separated by 10-500 μm, preferably 20-450 μm, more preferably 50-300 μm, even more preferably 70-250 μm. In one embodiment, the electrodes may be separated by a minimum distance of the abovementioned ranges. The electrodes may comprise an electrically-conductive material such as indium tin oxide alloy, platinum-iridium alloy, iridium, titanium, titanium alloy, stainless steel, gold, cobalt alloy, copper, aluminum, tin, iron, and/or some other metal or metal alloy. In a preferred embodiment, the electrodes comprise gold. In another preferred embodiment, the electrodes comprise platinum. In other embodiments, the electrodes may comprise a non-metallic electrically-conductive material, such as graphene or a polyelectrolyte. As defined here, an “electrically-conductive material” refers to substance with an electrical resistivity of at most 10⁻⁶ Ω·m, preferably at most 10⁻⁷ Ω·-m, more preferably at most 10−⁸ Ω·m at a temperature of 20-25° C. In one embodiment, a part of the electrically conductive material of the electrode may extend away from the substrate in order to connect with a power source to form part of a circuit. In one embodiment, the electrodes may be arranged in an interwoven, interdigitated, or comb-like pattern on the substrate. In one embodiment, two or more interdigitated patterns of electrodes may be electrically connected to each other, forming a continuous, single electrode. In another embodiment, two or more interdigitated electrodes may be electrically isolated from one another, and may function as parallel detector circuits within the room temperature hydrogen gas sensor. In one embodiment, the at least two electrodes are substantially planar. However, in other embodiments, the electrodes may be located on a surface of a curved or angled substrate, and may be non-planar. In another related embodiment, one or more of the at least two electrodes may be deposited on a location of a substrate having a high surface roughness, for instance an RMS greater than 20 nm, preferably greater than 50 nm, in which the at least two electrodes would not be considered planar. In this case, the electrodes may be formed on nanoparticles or a nano-pattered substrate. In one embodiment, the electrodes may have an average thickness of 100-500 nm, preferably 150-450 nm, more preferably 200-400 nm. The electrodes may be in the form of ribbons, wires, dots, or some other shape.

In one embodiment, the electrodes may be patterned on the substrate using known methods such as, for example, photolithography or electron beam lithography, and then wet or dry etching. Alternatively, a lift-off technique may be used, in which the electrode patterning is achieved by the dissolution of photoresist followed by deposition of a metallic layer of a photolithographically or e-beam lithographically defined photoresist layer.

In one embodiment, the SnO₂ layer has an average thickness of 10-700 nm, preferably 25-550 nm, more preferably 40-450 nm, even more preferably 50-400 nm. However, in some embodiments, the SnO₂ layer may have an average thickness of less than 10 nm or greater than 700 nm. In one embodiment, the SnO₂ layer may have a thickness that varies by less than 50 nm, preferably less than 35 nm, more preferably less than 25 nm of the average thickness. However, in some embodiments, the SnO₂ layer may have a thickness in some parts that is more than 50 nm or less than 50 nm of the average thickness.

In one embodiment, the SnO₂ layer consists essentially of SnO₂, meaning that the SnO₂ layer comprises at least 97 wt %, preferably at least 99 wt %, more preferably at least 99.9 wt % SnO₂ relative to a total weight of the SnO₂ layer. In one embodiment, the SnO₂ layer may comprise one or more compounds that are not SnO₂, for instance, the SnO₂ layer may comprise 1-4 wt %, or 2-3 wt % SnO (tin(II) oxide), relative to a total weight of the SnO₂ layer. In other embodiments, other semiconducting metal compounds or metal oxides may be used in place of or with the SnO₂. These include, but are not limited to, In₂O₃, ZnO, WO₃, Co₂O₃, TiO₂, NiO, ZrO₂, Fe₂O₃, Al₂O₃, Ga₂O₃, Nb₂O₅, and Sb₂O₃, n or any other semiconducting metal oxide, or a combination of one or more metals including In₂O₃ with ZnO, SnO₂ with ZnO, or any other combination of metals.

In one embodiment, the SnO₂ layer comprises polycrystalline SnO₂. “Polycrystalline,” as used herein, refers to material composed of multiple crystal grains that are typically separated by high-angle grain boundaries, i.e., boundaries between adjacent grains crystallographically misoriented by greater than 10°, preferably greater than 12°, more preferably greater than 15°. In one embodiment, the polycrystalline SnO₂ of the SnO₂ layer may be substantially, or even completely, free of any biaxial texture (e.g., a preferred grain-to-grain orientation).

In one embodiment, the SnO₂ layer comprises polycrystalline SnO₂ having an average grain size of 5-20 nm, preferably 5.5-15 nm, more preferably 6-10 nm, though in some embodiments, the SnO₂ layer may comprise polycrystalline SnO₂ having an average grain size of less than 5 nm or greater than 20 nm. In one embodiment, the SnO₂ layer may comprise monocrystalline SnO₂, or a mixture of amorphous SnO₂ and polycrystalline SnO₂.

In one embodiment, the grain size may be thought of as the longest distance through a central region of a crystal grain that connects opposite facing surfaces of the crystal grain. In one embodiment, the SnO₂ layer may have a lattice parameter or lattice constant (a) of 4.60-4.75 Å, preferably 4.62-4.72 Å, more preferably 4.68-4.70 Å. In one embodiment, the SnO₂ layer may have a lattice parameter or lattice constant (c) of 3.16-3.20 Å, preferably 3.16-3.19 Å, more preferably 3.17-3.18 Å. In one embodiment, the SnO₂ layer may show X-ray diffraction peaks corresponding to (110), (101), (200), (211), (220), (310), (112), and/or (321) SnO₂ crystal faces.

In one embodiment, the platinum layer has an average thickness of 1-15 nm, preferably 2-12 nm, more preferably 3-10 nm, even more preferably 4-8 nm. However, in some embodiments, the platinum layer may have an average thickness of less than 1 nm or greater than 15 nm. In an alternative embodiment, Pt nanoparticles having an average diameter of 1-15 nm, preferably 3-10 nm may be deposited on the SnO₂ layer. In another related alternative embodiment, other nanostructures of Pt or some other noble metal may be deposited on the SnO₂ layer, such as nanorods, nanowires, nanocubes, or nanoplatelets.

In one embodiment, the platinum layer has an RMS surface roughness of 0.1-4 nm, preferably 0.5-3.5 nm, more preferably 1-3 nm, even more preferably 1.2-2.5 nm. However, in other embodiments, the platinum layer may have an RMS surface roughness of less than 0.1 nm or greater than 4 nm.

In one embodiment, the Pt layer may completely cover the exposed SnO₂ layer. However, in other embodiments, the Pt layer may cover only 50-95 area %, preferably 60-90 area %, more preferably 70-85 area % of the total area of the exposed surface of the SnO₂ layer. In one embodiment, the Pt layer may be non-porous, though in some embodiments, the Pt layer may have pores, some of which may extend to the SnO₂ layer. In the embodiments where the SnO₂ layer does not cover all of the exposed substrate and electrodes, the Pt layer may be in direct contact with a part of the electrode and/or substrate.

In one embodiment, the room temperature hydrogen gas sensor, subjected to X-ray crystallography analysis, may show no measurable signal from the Pt layer due to its thinness and/or amorphous (non-crystalline) form. Thus, in some embodiments, the Pt layer may comprise crystalline Pt, and in other embodiments, the Pt may be in an amorphous state.

In one embodiment, the Pt layer consists essentially of Pt, meaning that the Pt layer comprises at least 97 wt %, preferably at least 99 wt %, more preferably at least 99.9 wt % Pt, even more preferably at least 99.99 wt % Pt relative to a total weight of the Pt layer.

In an alternative embodiment, a different metal may be used in place of or along with platinum. This metal may be palladium, gold, silver, aluminum, copper, iron, nickel, ruthenium, or some other metal or metal alloy.

In one embodiment, the Pt layer, or some other noble metal layer, may further comprise a polymer such as a polyamide, a polyacrylamide, a polyacrylate, a polyalkylacrylate, a polystyrene, a polynitrile, a polyvinyl, a polyvinylchloride, a polyvinyl alcohol, a polydiene, a polyester, a polycarbonate, a polysiloxane, a polyurethane, a polyolefin, a polyimide, or heteropolymeric combinations thereof. The polymer may be present at a weight percentage of 1-25 wt %, preferably 2-20 wt %, more preferably 3-8 wt % relative to the total weight of the Pt layer. In one embodiment, the Pt layer (or layer of some other material) on the SnO₂ layer may function as a molecular diffusion barrier, which is selectively permeable to diffusion of hydrogen gas to the exclusion of oxygen.

In one embodiment, both the SnO₂ layer consists essentially of SnO₂, and the Pt layer consists essentially of Pt.

In one embodiment, the SnO₂ layer may completely coat the electrodes and substrate, however, in other embodiments, the SnO₂ layer may cover only 50-90 area %, preferably 60-80 area % of the area of the total area of the exposed face of the electrodes and substrate. In one embodiment, the SnO₂ layer may be non-porous, though in some embodiments, the SnO₂ layer may have pores, some of which may extend to the substrate and/or electrode surface.

In one embodiment, the SnO₂ layer and/or the Pt layer may be partially or completely coated with materials such as nanostructured barium cerate, strontium cerate, or other proton conducting membranes or hydrogen permeable membranes to provide an effective barrier against non-hydrogen gases in the environment, yet enable only hydrogen to diffuse to interior of the room temperature hydrogen gas sensor, thereby acting as a selective membrane for hydrogen in the sensor element.

Preferably, the room temperature hydrogen gas sensor produces a change in electrical conductivity or resistivity upon exposure to hydrogen gas. Given Ohm's law, at a fixed electric potential (voltage), the conductivity is inversely proportional to the resistivity. Thus, the room temperature hydrogen gas sensor may be thought of as detecting a change in conductivity (i.e. current) or a change in resistivity. These changes may result from the adsorption of hydrogen gas molecules onto the surface of the room temperature hydrogen gas sensor. In view of that, the room temperature hydrogen gas sensor may also be referred to as a “chemiresistive hydrogen gas sensor.” However, in other embodiments, the room temperature hydrogen gas sensor may exhibit other measurable changes in physical properties such as optical transmittance, electrical capacitance, magneto-resistance, photoconductivity, and/or any other detectable property change accompanying the exposure of the room temperature hydrogen gas sensor to hydrogen. The room temperature hydrogen gas sensor may further include a detector constructed and arranged to convert the detectable change of physical property to a perceivable output, e.g., a visual output, auditory output, tactile output, and/or auditory output.

In a further embodiment, where the substrate comprises transparent silica, preferably quartz such as a quartz slide, the room temperature hydrogen gas sensor has a transmittance of 30-50%, for a wavelength in a range of 420-500 nm. Preferably the room temperature hydrogen gas sensor has a transmittance of 37-48% for a wavelength in a range of 420-480 nm. More preferably the room temperature hydrogen gas sensor has a transmittance of 42-45% for a wavelength in a range of 440-460 nm. However, in some embodiments, the transmittance may be lower than 30% or greater than 50% for a wavelength in a range of 420-500 nm. In some embodiments, the transmittance may be generally lower due to the substrate absorbing, reflecting, and/or scattering light, as compared to a substrate of transparent silica or quartz. In some embodiments, the transmittance of the room temperature hydrogen gas sensor may be generally higher at greater wavelengths and lower at shorter wavelengths, however, in alternative embodiments, the reverse may be true.

According to a second aspect, the present disclosure relates to a method of making the room temperature hydrogen gas sensor of the first aspect. This method involves the steps of sputtering SnO₂ onto the at least two electrodes on the substrate to produce an amorphous SnO₂ layer, sputtering platinum onto the amorphous SnO₂ layer to produce a deposited platinum layer; and annealing the amorphous SnO₂ layer and the deposited platinum layer.

In one embodiment, the SnO₂ layer and/or the Pt layer may be deposited by a sol-gel process. The sol-gel process is a versatile solution process for making ceramic and glass materials. In general, the sol-gel process involves the transition of a system from a liquid “sol” (mostly colloidal) into a solid “gel” phase. Applying the sol-gel process, it is possible to fabricate ceramic or glass materials in a wide variety of forms: ultra-fine or spherical shaped powders, thin film coatings, ceramic fibers, microporous inorganic membranes, monolithic ceramics and glasses, or extremely porous aerogel materials. The starting materials used in the preparation of the “sol” are usually inorganic metal salts or metal organic compounds such as metal alkoxides. In a typical sol-gel process, the precursor is subjected to a series of hydrolysis and polymerization reactions to form a colloidal suspension, or a “sol”. Further processing of the “sol” enables one to make ceramic materials in different forms. Thin films can be produced on a piece of substrate by spin-coating or dip-coating. When the “sol” is cast into a mold, a wet “gel” will form. With further drying and heat-treatment, the “gel” is converted into dense ceramic or glass articles. If the liquid in a wet “gel” is removed under a supercritical condition, a highly porous and extremely low density material called “aerogel” is obtained. As the viscosity of a “sol” is adjusted into a proper viscosity range, ceramic fibers can be drawn from the “sol.” Ultra-fine and uniform ceramic powders are formed by precipitation, spray pyrolysis, or emulsion techniques. In one embodiment, the SnO₂ and/or the Pt may be deposited by electron beam deposition, chemical vapor deposition, wet deposition, or some other technique. In one embodiment, the SnO₂ and/or the Pt may be sputtered, for instance, by a RF sputtering mode, a magnetron sputtering mode, or a DC sputtering mode. In one embodiment, the SnO₂ is sputtered by a RF sputtering mode, and the Pt is sputtered by a DC sputtering mode.

Where the SnO₂ and/or Pt are sputtered, a sputtering chamber may be used that is evacuated to a base pressure of less than 3.5×110 Torr, preferably less than 3.0×10⁻⁶ Torr. Then, the sputtering chamber is filled with argon gas, or a gas mixture comprising 5-20 vol %, preferably 10-18 vol %, more preferably 12-16 vol % oxygen in argon gas, relative to a total volume of the gas mixture. The pressure of the argon or the gas mixture (i.e. working pressure) may be maintained in the range of 0.5-10 mTorr, preferably 1-6 mTorr in the sputtering chamber during sputtering. A sputtering power may be set to a value in the range of 10 to 500 W, preferably 20 to 180 W. An SnO₂ source may be used for sputtering the SnO₂ onto the substrate, and a Pt source may be used for sputtering the Pt onto the SnO₂. The distance between the target and the substrate may be 5-20 cm, preferably 7-15 cm, more preferably 8-12 cm. The substrate may be maintained at room temperature, or at 20-35° C., preferably 22-32° C., more preferably 26-30° C. In one embodiment, the SnO₂ may be sputtered for 0.5-4 h, preferably 1-3 h, more preferably 1.5-2.5 h, and the Pt may be sputtered for 15 s-2 min, preferably 30 s-1.5 min, or about 1 min.

Following the deposition of the SnO₂ and Pt, the amorphous SnO₂ layer and the deposited Pt layer may be annealed in an oven at a temperature of 130-250° C., preferably 135-220° C., more preferably 138-210° C., even more preferably 140-200° C., to produce the room temperature hydrogen gas sensor. In another embodiment, the temperature may be 130-200° C., preferably 135-180° C., more preferably 140-170° C., even more preferably 145-155° C., or about 150° C. However, in some embodiments, the annealing may be carried out at temperatures lower than 130° C., such as 128° C., or greater than 250° C., such as 275-325° C., 425-475° C., 550-650° C., or even greater temperatures.

In one embodiment, the annealing temperature may affect the crystal grain size of the SnO₂ in the SnO₂ layer, and thus change the sensitivity or functioning of the room temperature hydrogen gas sensor in H₂ detection. The amorphous SnO₂ layer and the deposited Pt layer may be annealed in an atmosphere of air, or in an atmosphere consisting essentially of an inert gas, such as N₂ or argon.

In one embodiment, the annealing may be carried out for 1-5 hours, preferably 2-4 hours, more preferably 2.5-3.5 hours, or about 3 hours, however, in some embodiments, the annealing may be carried out for less than 1 hour or greater than 5 hours. In a preferred embodiment, the annealing is carried out for 1-5 hours at a temperature of 140-170° C., preferably 2-4 hours at a temperature of 145-155° C., even more preferably about 3 hours at a temperature of about 150° C. In one embodiment, for the annealing step, the amorphous SnO₂ layer and the deposited Pt layer may be placed in an oven heated at 130-250° C. or any of the above annealing temperature ranges. In another embodiment, the amorphous SnO₂ layer and the deposited Pt layer may be placed in an oven at room temperature, and then heated to one of the above annealing temperatures at a rate of 0.5-10° C./min, preferably 1.0-5° C./min, more preferably 1.5-4° C./min. However, in some embodiments, the oven may be heated at a rate slower than 0.5° C./min or faster than 10° C./min. In one embodiment, following the annealing time, the oven may be turned off with the room temperature hydrogen gas sensor inside and allowed to cool to room temperature. In another embodiment, the room temperature hydrogen gas sensor may be taken out and placed in a room temperature environment in order to cool. In another embodiment, the room temperature hydrogen gas sensor may be cooled with a stream of inert gas, such as nitrogen or argon.

In one embodiment, in the entire method of making the room temperature hydrogen gas sensor as described above, starting with the sputtering, the amorphous SnO₂ layer and the deposited platinum layer are exposed to temperatures no greater than 200° C., preferably no greater than 180° C., more preferably no greater than 160° C., even more preferably no greater than 155° C. In other words, the method of making the room temperature hydrogen gas sensor does not involve heating, annealing, or exposing any materials to temperatures greater than 200° C., preferably no greater than 180° C., more preferably no greater than 160° C., even more preferably no greater than 155° C.

In an alternative embodiment, the substrate, electrodes, and amorphous SnO₂ layer may be annealed before depositing the Pt layer. In another alternative embodiment, crystalline particles of SnO₂, produced by annealing or some other process, may be deposited on the substrate and electrodes, without any further requirement for annealing.

The room temperature hydrogen gas sensor, or its precursor material (substrate, amorphous SnO₂ layer, etc.) at any step of its synthesis, may be characterized by a variety of techniques. Exemplary techniques include, but are not limited to, electron microscopy (TEM, SEM), atomic force microscopy (AFM), ultraviolet-visible spectroscopy (UV-Vis), dynamic light scattering (DLS), X-ray photoelectron spectroscopy (XPS), X-ray fluorescence (XRF), powder X-ray diffraction (XRD), energy dispersive X-ray spectroscopy (EDX), thermogravimetric analysis (TGA), Fourier transform infrared spectroscopy (FTIR), matrix-assisted laser desorption/ionization time-of-flight mass spectrometry (MALDI-TOF), Rutherford backscattering spectrometry (RBS), dual polarization interferometry, time-of-flight secondary ion mass spectrometry (ToF-SIMS), electron energy loss spectroscopy (EELS), high-angle annular dark field (HAADF), near infrared (NIR) spectroscopy, nuclear magnetic resonance (NMR), or combinations thereof.

According to a third aspect, the present disclosure relates to a method of using the room temperature hydrogen gas sensor of the first aspect. This method involves contacting the platinum layer with a first gas sample comprising hydrogen gas, and measuring a first resistivity across the at least two electrodes. Here, the first resistivity is decreased by 70-99.9% relative to a second resistivity arising from a second gas sample, where the second gas sample is substantially free of hydrogen gas. The second gas sample may be measured before and/or after the first gas sample. In some embodiments, the second gas sample may be considered a gas blank sample, as it is intended to not produce a detection signal as would as gas sample comprising H₂ gas. In some embodiments, the first resistivity is decreased by 75-95%, preferably 78-92%, more preferably 80-90% relative to a second resistivity. In some embodiments, the first resistivity is decreased by 10-75%, preferably 20-60%, more preferably 30-50% relative to a second resistivity. However, in some embodiments, the first resistivity may be decreased by smaller than 10% or larger than 99.9% relative to a second resistivity. In some embodiments, this percentage decrease may be considered a “response” of the room temperature hydrogen gas sensor. Preferably, the magnitude of the percentage decrease is dependent on the concentration of H₂ gas in contact with the room temperature hydrogen gas sensor. For instance, in one embodiment, a H₂ gas concentration of 200-500 ppm may produce a response of 45-85%, preferably 50-82%, more preferably 70-80%. A H₂ gas concentration of 600-900 ppm may produce a response of 65-95%, preferably 80-90%, more preferably 85-92%. A H₂ gas concentration of 1,100-1,400 ppm may produce a response of 70-97%, preferably 85-96%, more preferably 90-95%. A H₂ gas concentration of 1,500-2,000 ppm may produce a response of 75-99.9%, preferably 80-99%, more preferably 92-98%.

In one embodiment, a gas sample may originate from an ambient indoor environment, for example, of a residence, a factory, a store, a hospital, a car, or some other indoor environment. In another embodiment, a gas sample may come from an outdoor environment, or from a cave, a mine, or a geothermal vent. In another embodiment, a gas sample may come from a vessel or tubing of a laboratory or a chemical processing plant, where H₂ may be a main product, a byproduct, or a contaminant. In one embodiment, the H₂ may be the product of water splitting or may be used in a hydrogen fuel cell to extract power.

In one embodiment, the gas sample may be diluted, concentrated, pressurized, depressurized, dried, heated, or cooled before contacting the room temperature hydrogen gas sensor.

In one embodiment, the room temperature hydrogen gas sensor may be housed in a casing designed for portability. In another embodiment, the room temperature hydrogen gas sensor may be housed in a casing for fixing or securing to a wall or to connect with a vessel or tubing. In one embodiment, the room temperature hydrogen gas sensor may be operated continually, similar to other emergency detectors (such as a smoke detector), and may have a set threshold of H₂ gas concentration beyond which an audible and/or visible alarm is triggered.

In one embodiment, the method of using the room temperature hydrogen gas sensor further comprises a calibration process. For instance, gas samples comprising known concentrations of H₂ may be brought into contact with the room temperature hydrogen gas sensor, and the corresponding response may be measured. A person having ordinary skill in the art would be able to construct a calibration curve or plot based on the measured response of the room temperature hydrogen gas sensor when in contact with the different known gas samples.

In one embodiment, the first gas sample comprises 50-1800 ppm hydrogen gas, preferably 200-1700 ppm, more preferably 500-1250 ppm hydrogen gas. However, in some embodiments, the first gas sample may comprise less than 50 ppm hydrogen gas or greater than 1800 ppm hydrogen gas.

In one embodiment, the first gas sample has a temperature of 0-50° C., preferably 15-40° C., more preferably 20-35° C., even more preferably 22-28° C. However, in some embodiments, the first gas sample may have a temperature of less than 0° C. or greater than 50° C.

In one embodiment, the first gas sample may have a total pressure of 0.9-1.1 atm, preferably 0.92-1.08 atm, more preferably 0.95-1.05 atm. However, in some embodiments, the first gas sample may have a total pressure of less than 0.9 atm or greater than 1.1 atm.

In one embodiment, the second gas sample comprises 300-5,000 ppm, preferably 350-3,000 ppm, more preferably 400-2,000 ppm, even more preferably 500-1,500 ppm of at least one gas selected from the group consisting of NH₃, n-butane, O₂, CO₂, and N₂. However, in some embodiments, the second gas sample may comprise less than 300 ppm or greater than 5,000 ppm of at least one gas selected from the group consisting of NH₃, n-butane, O₂, CO₂, and N₂, or may comprise some other gas, such as methane. In one embodiment, the second gas sample may comprise N₂ at a concentration of 100-5,000 ppm, preferably 500-2,000 ppm, more preferably 800-1,200 ppm. In one embodiment, the second gas sample may comprise n-butane at a concentration of 100-5,000 ppm, preferably 500-2,000 ppm, more preferably 800-1,200 ppm. In one embodiment, the second gas sample may comprise NH₃ at a concentration of 50-1,000 ppm, preferably 100-800 ppm, more preferably 200-600 ppm. In one embodiment, the second gas sample may comprise CO₂ at a concentration of 100-5,000 ppm, preferably 500-2,000 ppm, more preferably 800-1,200 ppm.

In one embodiment, the second gas sample may have a total pressure of 0.9-1.1 atm, preferably 0.92-1.08 atm, more preferably 0.95-1.05 atm. However, in some embodiments, the second gas sample may have a total pressure of less than 0.9 atm or greater than 1.1 atm.

In one embodiment, a gas sample in contact with the room temperature hydrogen gas sensor includes hydrogen gas and at least one compound selected from the group consisting of NH₃, n-butane, O₂, CO₂, N₂, pentane, butene, and pentene, wherein a hydrogen selectivity of the hydrogen gas sensor is at least 70% by mole, preferably at least 80% by mole, more preferably at least 85% by mole. As used herein, the term “hydrogen selectivity” refers to a ratio of a number of moles of the hydrogen gas that are adsorbed onto the room temperature hydrogen gas sensor relative to the total number of moles of gas molecules that are adsorbed onto the zinc oxide nanostructured thin film. For example, a hydrogen selectivity of the 80% by mole refers to an embodiment wherein 80% of all species adsorbed onto the room temperature hydrogen gas sensor are hydrogen. The hydrogen selectivity may be related to the specific surface area and the concentration of oxygen vacancies of the room temperature hydrogen gas sensor.

In one embodiment, the decrease in the first resistivity has a response time of 0.5-100 s, preferably 20-90 s, more preferably 40-80 s. However, in some embodiments, the response time may be shorter than 0.5 s or longer than 100 s. As defined here, the response time is the time needed by the room temperature hydrogen gas sensor to attain 90% of its saturation state value (i.e., the saturation state value may be thought of as the maximum response for a specific gas sample). The recovery time is defined as the time required for the maximum response to return to this 90% saturation state value once the particular gas sample is removed or exchanged with a gas producing essentially no response signal. In one embodiment, the decrease in the first resistivity may have a recovery time of 200-400 s, preferably 250-380 s, more preferably 280-360 s. However, in some embodiments, the recovery time may be shorter than 200 s or longer than 400 s. Generally, in some embodiments, as the concentration of H₂ in a gas sample increases, the recovery time increases and/or the response time decreases. However in some embodiments and/or certain concentration ranges, the concentration of H₂ may increase while the response time and/or recovery time may be essentially unchanged. In alternative embodiments, the response time and/or the recovery time may be defined by the time it takes the response signal to reach a percentage lower than or greater than 90% of the saturation state value.

In one embodiment, the second gas sample comprises 0.1-99 vol %, preferably 1-90 vol %, more preferably 10-80 vol %, even more preferably 15-70 vol %, or 20-60 vol %, or 0-10 vol %, 10-20 vol %, 20-30 vol %, 30-40 vol %, 40-50 vol %, 50-60 vol %, 60-70 vol %, 70-80 vol %, 80-90 vol %, 90-99 vol % of at least one gas selected from the group consisting of O₂, CO₂, H₂O, Ar, and N₂, relative to a total volume of the second gas sample. In another embodiment, the second gas sample consists essentially of O₂, CO₂, H₂O, Ar, and/or N₂. Where the second gas sample consists essentially of O₂, CO₂, H₂O, Ar, and/or N₂, the second gas sample may comprise 99.999 vol %, preferably 99.9999 vol %, more preferably 99.99999 vol % O₂, CO₂, H₂O, Ar, and/or N₂ relative to a total volume of the second gas sample. In other words, where the second gas sample consists essentially of O₂, CO₂, H₂O, Ar, and/or N₂, the second gas sample comprises O₂, CO₂, H₂O, Ar, and/or N₂ and less than 100 ppm of other gases, preferably less than 10 ppm of other gases, more preferably less than 1 ppm of other gases. In one embodiment, the second gas sample may be air, for example, from an indoor or outdoor environment. The air may comprise 75-80 vol % N₂, 18-22 vol % O₂, 0-1.2 vol % Ar, 0-0.05 vol % CO₂, and 0-2 vol % H₂O.

In one embodiment, the room temperature hydrogen gas sensor is in contact with 500-5,000 ppm H₂ gas, preferably 500-5,000 ppm H₂ gas, more preferably 500-5,000 ppm H₂ gas for a time period before the contacting with the first gas sample. The time period may be 1-6 months, preferably 1.5-5 months, more preferably 2-4 months. However, in some embodiments, the time period may be shorter than 1 month or longer than 6 months, and the concentration of H₂ gas may be less than 500 ppm or greater than 5,000 ppm.

In one embodiment, the method has a repeatability of at least 99%, preferably, at least 99.5%, over a time period of at least one hour, preferably at least one month, more preferably, at least one year. In one embodiment, the method has a repeatability of at least 99%, preferably at least 99.5% for at least 4 separate instances of contacting with H₂ gas, preferably at least 10 separate instances, more preferably at least 100 separate instances, even more preferably at least 1,000 separate instances. In other embodiments, the method may have a repeatability of at least 65%, at least 70%, at least 75%, at least 80%, at least 85%, at least 90% or at least 95% for any of the previously mentioned number of instances or time intervals. As defined here, repeatability refers to the percentage of a response, relative to the response of an initial measurement, for an identical gas sample or control being measured more than once. For instance, a room temperature hydrogen gas sensor may have an initial response of 75 kΩ for a gas sample of 1500 ppm H₂ in N₂. After numerous measurements, the same gas sample may then produce a response of 72 kΩ, which indicates a repeatability of 72/75×100%=96%.

In one embodiment, the method may further comprise a step of cleaning or recharging the sensor. Here, the sensor may be heated above room temperature, for instance, to 80-120° C., 120-200° C., or 200-500° C. and/or may be contacted with one or more compounds such a solvent or an acid, in order to remove impurities, though in other embodiments, the cleaning may involve exposure to light irradiation, such as with UV light. In one embodiment, the cleaning or recharging may increase the repeatability of a room temperature hydrogen gas sensor.

The room temperature hydrogen gas sensor may further be utilized to detect and/or determine a concentration of other gaseous compounds that affect its electrical resistance upon adsorption. Exemplary gaseous compounds without limitations may include carbon monoxide, nitrogen monoxide, nitrogen dioxide, methane, ethane, methanol, ethanol, hydrogen sulfide, etc. In view of that, the room temperature hydrogen gas sensor may also be used to detect exhaust gases or toxic gases, for example, in automobile industries and/or in air pollution control systems.

In an alternative embodiment, a room temperature hydrogen gas sensor may be used in the field of batteries, fuel cells, photo-chemical cells, heated hydrogen sensors, semiconductors (such as field effect transistors), magnetic semiconductors, capacitors, data storage devices, biosensors (such as redox protein sensors), photovoltaic, liquid crystal screens, plasma screens, touch screens, OLEDs, antistatic deposits, optical coatings, reflective coverings, anti-reflection coatings, and/or reaction catalysis. Similarly, in one embodiment, the room temperature hydrogen gas sensor may be coated with another material. For example, the room temperature hydrogen gas sensor may be coated with a layer of gold. A gold-coated nanostructured room temperature hydrogen gas sensor may then be used for detection of H₂ or some other analyte using surface enhanced Raman spectroscopy (SERS).

In one embodiment, two or more separate substrates having electrodes with SnO₂ and Pt layers may be connected in series and/or parallel in order to create an array of room temperature hydrogen gas sensors.

The examples below are intended to further illustrate protocols for preparing, characterizing the room temperature hydrogen gas sensor, and uses thereof, and are not intended to limit the scope of the claims. In the examples, “sample” and “sensor” may be used interchangeably to describe the room temperature hydrogen gas sensor.

### Example 1

### Fabrication of RT (Room Temperature) Hydrogen Sensor

Nano-structured SnO₂ and Pt/SnO₂ thin films were synthesized by a DC/RF sputtering technique (model NSC-4000, Nanomaster, USA) on quartz substrates as well as on SiO₂ substrates with pre-interdigitated Au electrodes (200 nm thick with 250 μm interspace distances). The quartz substrates were used to carry out the structural, compositional, morphological, and optical analysis while the pre-interdigitated Au electrodes were used to study the gas sensing properties. Before loading the substrates into the deposition chamber, the substrates were sonicated in acetone for 35 min. followed by blow-drying with N₂ gas and drying in an oven at 120° C. for 30 min.

The SnO₂ and Pt targets were cleaned by pre-sputtering for 3 min and 1 min, respectively. The sputtering conditions for the fabrication of pristine SnO₂ and Pt/SnO₂ are listed in Table 1. For the synthesis of heated Pt/SnO₂ films, a layer of SnO₂ thin film was fabricated by RF sputtering followed by sputter deposition of a very thin layer of Pt. Finally, heat treatments at 150° C., 300° C., 450° C., and 600° C. were carried out for a duration of 3 h in argon atmosphere to ensure stability, as well as enhance the conductivity and the crystallinity of the grown samples. The fabricated sensors have been designated: as-deposited SnO₂ (S1), as-deposited Pt/SnO₂ (S2), Pt/SnO₂ post annealed at 150° C. (S3), Pt/SnO₂ post annealed at 300° C. (S4), Pt/SnO₂ post annealed at 450° C. (S5), and Pt/SnO₂ post annealed at 600° C. (S6). Various characterization techniques were performed to investigate the structural, morphological, compositional, and optical properties. The topography of the films was investigated with Atomic Force Microscopy (AFM, Dimension Icon, Bruker) operating in the ScanAsyst mode. Structural characterization of the prepared films was carried out using XRD (Rigaku Miniflex 600 X-Ray Diffraction (XRD), with Cu K irradiation at λ=1.5406 Å). The 2θ range was set to 20°-80° with a scan speed of 1°/min. Optical transmittance was carried out using a double beam UV/Vis spectrophotometer (Jasco V-570) in the wavelength range of 200-800 nm. The films' chemistry was studied by X-ray photoelectron spectroscopy (XPS, Model: ESCALAB250Xi).

TABLE 1
RF and DC experimental sputtering conditions for as-deposited SnO₂ and
Pt/SnO₂ thin films.

| | SnO₂ thin | |
|---|---|---|
| Parameter | Films | Pt thin Films |
| Sputtering mode | RF | DC |
| Source material | SnO₂ (99.99) | Pt (99.99) |
| Base pressure (Torr) | 1.6 * 10⁻⁶ | 3.1 * 10⁻⁶ |
| Working pressure (Torr) | 5.6 * 10⁻³ | 5.6 * 10⁻³ |
| Flow of Ar (SCCM) | 60 | 60 |
| Flow of O₂ (SCCM) | 10 | 0 |
| Power (W) | 150 | 30 |
| Target-substrate distance (cm) | 10 | 10 |
| Substrate temperature (K) | 301 | 301 |
| Sputtering time (min.) | 120 | 1 |

### Example 2

### Gas Sensing Measurements

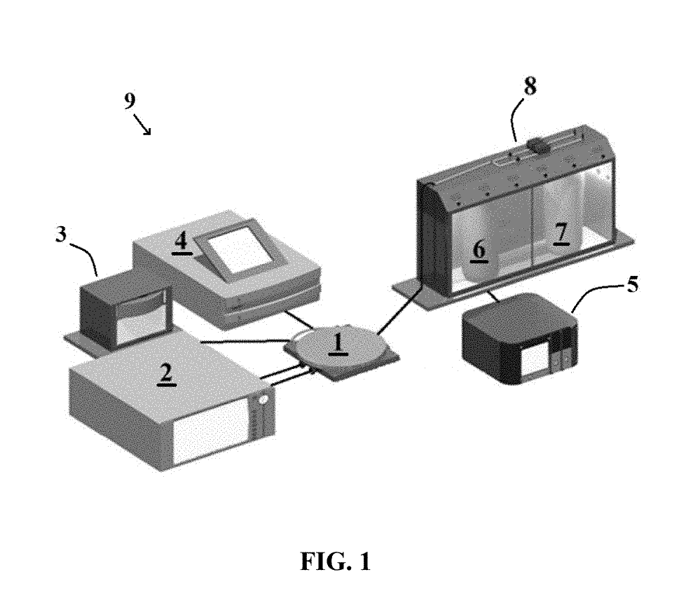

The chemical sensing system 9 used in this work is schematically shown in FIG. 1. The H₂ sensing behavior of the fabricated sensors were investigated using a test-stage, namely LINKAM stage 1 (Model HFS-600E-PB4, UK), procured from Linkam Scientific Instruments. The LINKAM stage temperature could be heated between RT and 600° C. by a temperature controller 4 and could be cooled rapidly with temperature stability <0.1° C. using a water cooling 3. The test-stage was connected to two mass flow controllers 8 (MFCs) controlled via an external X PH-100 power hub supply 5: one MFC was for 1% H₂/balance N₂ 6, and one MFC was for dry air 7. The H₂ concentration (C_{H}_{₂}: in ppm) in the chamber was measured via the following formula:

$${C}_{{H}_{2}} = C \times \frac{{F}_{{H}_{2}}}{{F}_{T}}$$

where C is the hydrogen concentration in the cylinder (10,000 ppm), F_{H}_{₂} is the flow of 1% H₂/balance N₂, and FT is the total flow (hydrogen balance with nitrogen and the flow from the dry-air tank). Prior to each test, the chamber was purged with 50 sccm (standard cubic centimeter per minute) for at least 1 h to stabilize the system before being supplied with the H₂. The response of the sensor is defined as:

$$Response ( \% ) = \frac{{R}_{0} - {R}_{g}}{{R}_{0}} \times 100$$

Here, the R₀ and R_{g} are the sensor resistance in air and in H₂ test gas, respectively. The resistance was measured by an Agilent B1500A Semiconductor Device Analyzer (SDA) 2. The sensor response was investigated in the 250-1750 ppm concentration range of H₂ gas in dry air at an operating temperature range of RT—500° C.

### Example 3

### Characterization of RT Hydrogen Sensor

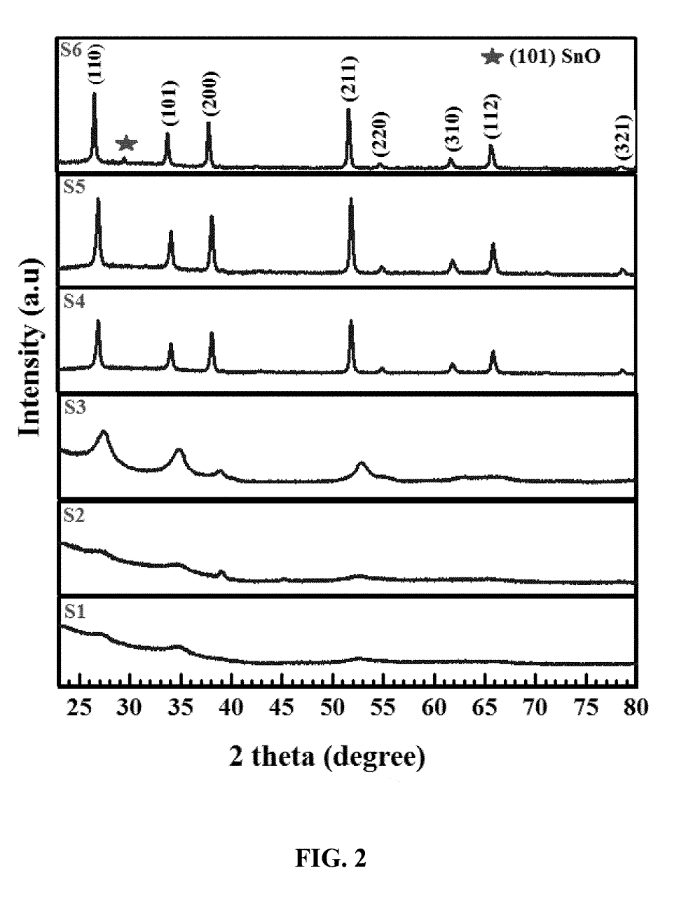

The XRD patterns of the obtained thin films are shown in FIG. 2. The identification of the diffracted SnO₂ peaks was based on the International Center for Diffraction Data, card no. 041-1445. As shown in sample S2 in FIG. 2, the as-deposited Pt/SnO₂ film has an amorphous structure with very weak (110), (101), and (211) diffraction peaks. Upon heat treatment at 150° C., the amorphous structure of the film was transformed into the polycrystalline tetragonal rutile structure of SnO₂, as indicated by the occurrence of broad diffraction peaks along the (110), (101), (200), and (211) growth directions in sample S3. Further annealing at 300° C. or 450° C. (S4 and S5 films) led to improved crystallinity of the films, as can be seen from the sharpness of the above-mentioned diffraction peaks. Furthermore, four more diffraction peaks corresponding to the (220), (310), (112), and (321) direction were observed. This re-crystallization could be attributed to post annealing minimizing the energy of growth along these directions. Upon increasing the annealing temperature to 600° C., the intensities of the diffraction peaks were not only enhanced, but a SnO phase was formed, as indicated by the appearance of the new (101) peak. The absence of any diffraction peaks due to Pt in the as-deposited Pt/SnO₂ and heated Pt/SnO₂ films indicates Pt's amorphous nature in these films and/or its very small doping percentage.

The average grain size (D) of the nanostructured SnO₂ in the annealed Pt/SnO₂ films (S3-S6 films) was calculated using Scherrer's equation:

$$D = \frac{K λ}{β Cos θ}$$

where λ is the wavelength of the incident X-ray, K is a constant, β is the full width at the half of the peak maximum, and θ is the Bragg angle. See P. Bindu, S. Thomas. Estimation of lattice strain in ZnO nanoparticles: X-ray peak profile analysis. J. Theor. Appl. Phys. 8 (2014)123-134, incorporated herein by reference in its entirety. The values of the average grain size are listed in Table 2. The agglomeration of particles increases with annealing, which explains the increase of the grain size as annealing temperature increases. See J. Ungula, B. F. Dejene, and H. C. Swart. Effect of annealing on the structural, morphological and optical properties of Ga-doped ZnO nanoparticles by reflux precipitation method. Results in Physics 7 (2017) 2022-2027, incorporated herein by reference in its entirety. In addition, the lattice constants (a) and (c) of the SnO₂ were calculated using formula:

$$\frac{1}{{d}^{2}} = \frac{{h}^{2} + {k}^{2}}{{a}^{2}} + \frac{1}{{c}^{2}}$$

where hkl are the Miller indices. See A. S. Manikandan, K. B. Renukadevi. Influence of fluorine incorporation on the photocatalytic activity of tin oxide thin films. Materials Research Bulletin 94 (2017) 85-91, incorporated hereby by reference in its entirety. The results, listed in Table 2, are in a good agreement with the standard values for SnO₂ (a=4.73 Å, c=3.18 Å). See Joint Committee on Powder Diffraction Standards (JCPDS), International Centre for Diffraction Data: Newtown Square, Pa., USA, 1997, incorporated herein by reference in its entirety.

TABLE 2
Grain size, lattice parameters, and RMS of the fabricated thin films.

| | | Lattice | | |
|---|---|---|---|---|
| Sample | Grain size (nm) | parameter (a) | Lattice parameter (c) | RMS |
| S1 | — | — | — | 5 |
| S2 | — | — | — | 4 |
| S3 | 7 | 4.690 | 3.172 | — |
| S4 | 39 | 4.728 | 3.178 | — |
| S5 | 42 | 4.736 | 3.185 | — |
| S6 | 63 | 4.741 | 3.192 | 2 |

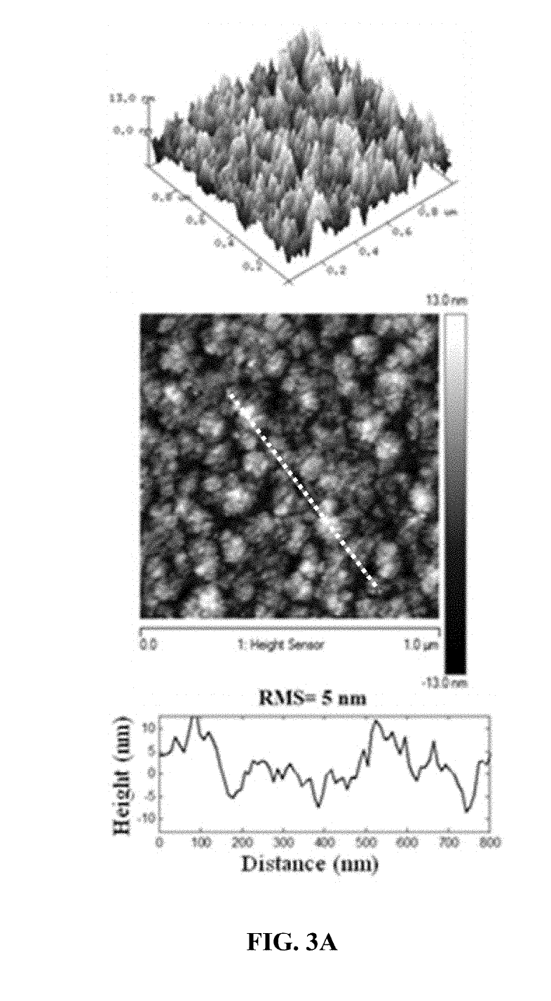

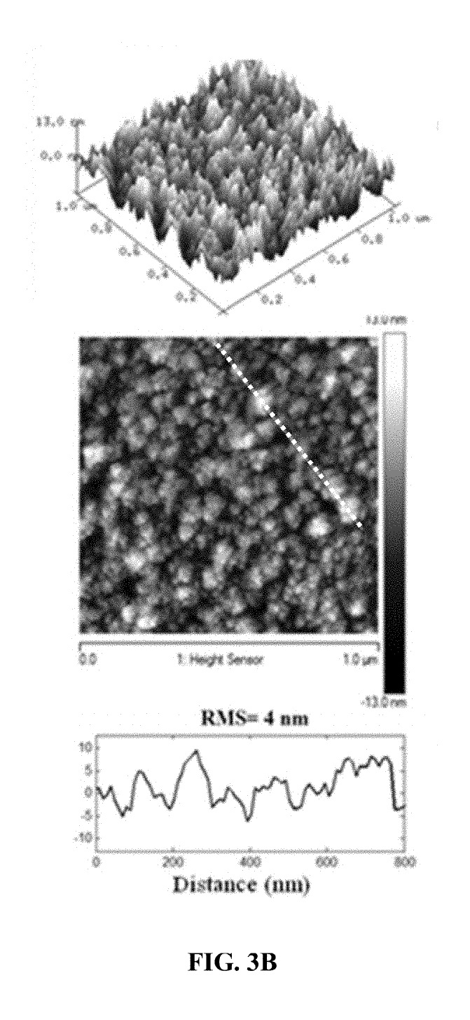

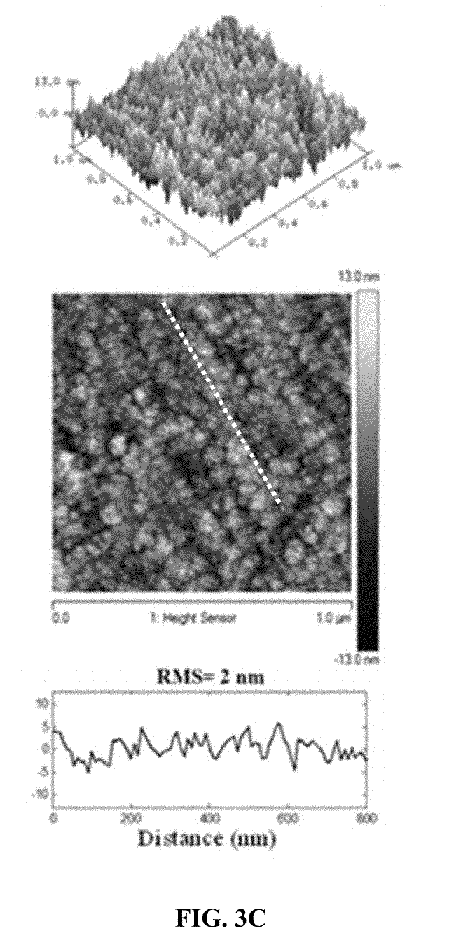

FIGS. 3A, 3B, and 3C show AFM images (3D, 2D, and linear surface profiles) and the calculated root mean square (RMS) surface roughness values of the S1, S2, and S6 samples, respectively. It can be seen that all surfaces are of porous structure consisting of grains with small crystal sizes and voids between them. The 2D AFM images of the S1 and S2 films show voids between the grains, which become closely packed in the S6 film. It can also be seen from the 3D AFM images that all three sample films have a columnar structure. The RMS surface roughness for S1, S2, and S6 are 5, 4, and 2 nm, respectively. The very low values of the RMS surface roughness indicate the uniform and homogeneous surface of the fabricated films.

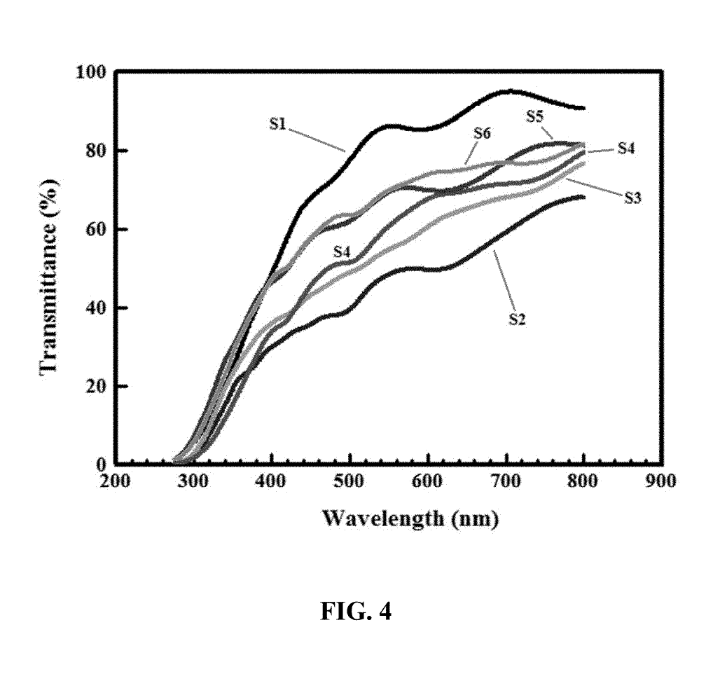

The transmittance spectra of the fabricated films are shown in FIG. 4. The interference fringes appearing in the visible range originate from light interference at the film-air and the substrate-film interfaces. See S. Cho. Effect of growth temperature on structural. Electrical, and optical properties of Gd-doped zinc oxide films. Phys. Status Solidi A 3 (2014) 709-13, incorporated herein by reference in its entirety. As can be seen from FIG. 4, the S1 (pristine SnO₂) thin film is highly transparent in the visible and the infra-red regions of the spectrum. However, decoration with Pt (S2 film) led to a significant decrease in the transparency of SnO₂. This could be attributable to the optical scattering caused by the Pt decoration of the SnO₂ surface. See J. Lee, and B. Park. Transparent conducting ZnO:Al, In and Sn thin films deposited by the sol-gel method. Thin Solid Films 426 (2003) 94-99, incorporated herein by reference in its entirety. Upon heat treatment, the transparency of the S2 film was enhanced (S3-S6 films).

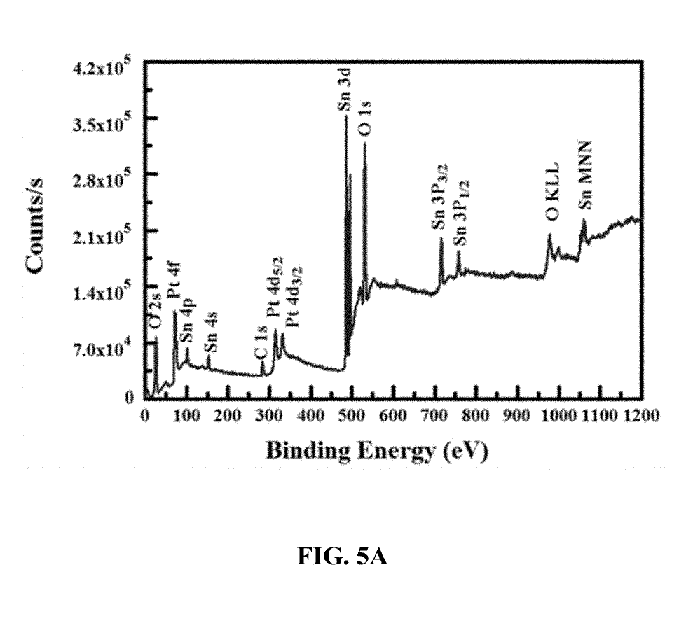

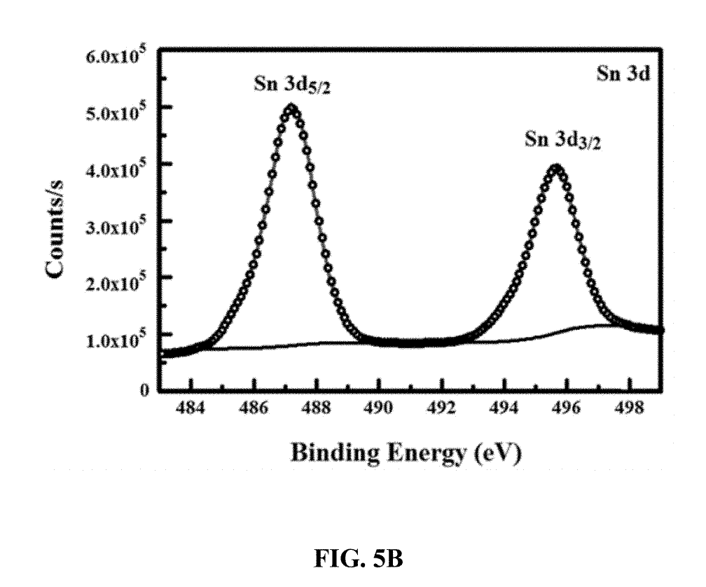

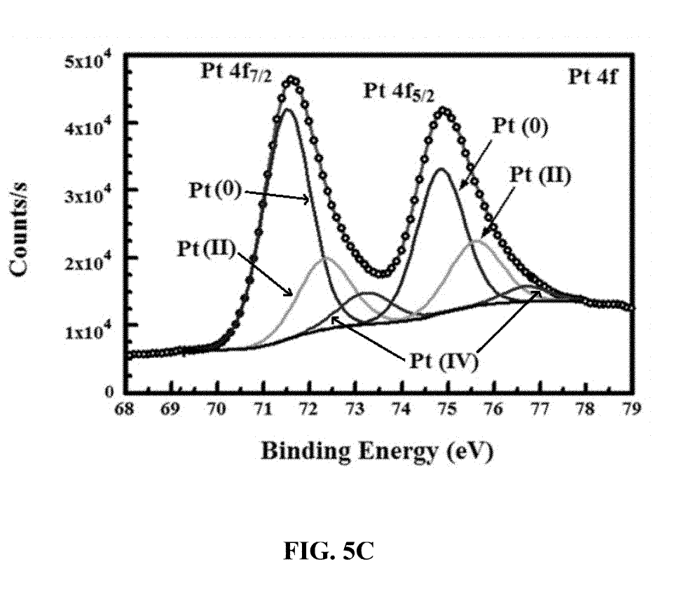

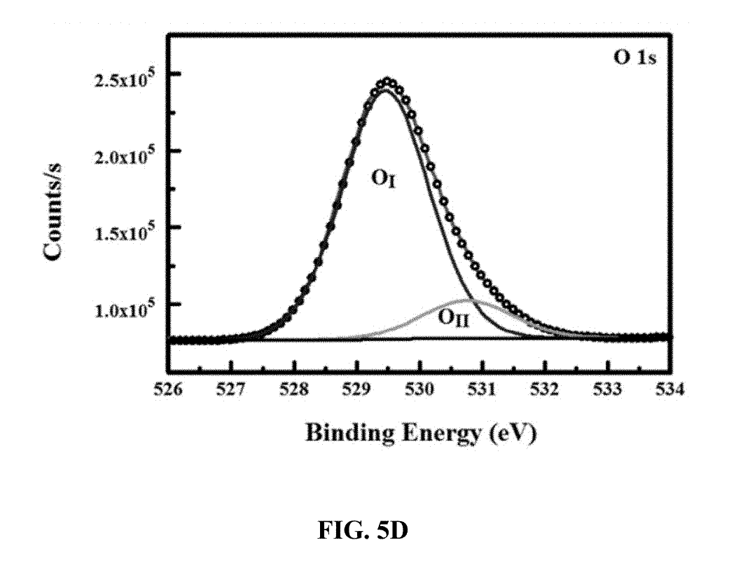

The chemical composition of the fabricated films was performed by XPS (X-Ray Photoelectron Spectroscopy). A typical XPS survey spectrum, and spectra of Sn 3d, Pt 4f, and O is core-level spectra for the S3 sample are shown in FIGS. 5A-5D. Only the related core-levels of the constituent elements (Sn, Pt, and O) are observed in the survey spectrum (FIG. 5A). The Sn 3d core level spectrum comprises doublet peaks assigned to Sn 3d_{5/2} and Sn 3d_{3/2} due to spin-orbit splitting. The oxidation state in each film was determined by deconvoluting the Sn 3d XPS spectra. For samples S1, S2, and S3, each deconvoluted spectrum consisted of two peaks located in the binding energy range of 486.9-487.1 eV and 494.5-497.0 eV, corresponding to Sn 3d_{5/12} and Sn 3d_{3/2} of the Sn (IV) oxidation state. See Q. Ni, D. W. Kirk, and S. J. Thorpe. Characterization of the mixed oxide layer structure of the Ti/SnO₂—Sb₂O₅ anode by photoelectron spectroscopy and impedance spectroscopy. Journal of the Electrochemical Society 162 (2015) H40-H46; and Y. Wang, M. Aponte, N. Leon, I. Ramos, R. Furlan, and N. Pinto. Synthesis and characterization of ultra-fine tin oxide fibers using electrospinning. J. Am. Ceram. Soc., 88 (2005) 2059-2063, each incorporated herein by reference in their entirety. No additional peaks belonging to other oxidation states were observed in the resolved Sn 3d spectra of these samples, confirming the stoichiometry of the obtained films. FIG. 5B shows representative resolved Sn 3d XPS spectrum for S3. For samples S4, S5 and S6, each Sn 3d XPS spectrum was resolved into two pairs of Sn 3d_{5/2} and Sn 3d_{3/2} peaks. Two peaks positioned at high binding energies were assigned to Sn(IV) oxidation state, and two small peaks positioned at low binding energies were ascribed to Sn(II) oxidation state. See Q. Ni et al.; Y. Wang et al.; and C. D. Wagner, A. V. Naumkin, A. Kraut-Vass, J. W. Allison, C. J. Powell, J. R. Jr. Rumble, NIST, Standard Reference Database 20, Version 3.4 (web version) (http://srdata.nist.gov/xps/) 2003, each incorporated herein by reference in their entirety. The binding energy and the weight of each component in Sn 3d₅₂ region for each film are listed in Table 3. It can be seen clearly from Table 3 that the weight of the Sn(II) component increased with annealing to reach almost 16% of the total Sn 3d peak in sample S6. Such a result is evidenced by the appearance of the XRD diffraction peak of the said compound in the XRD spectrum of this sample.

Similarly, the Pt 4f core-level spectrum is composed of Pt 4f_{7/2} and Pt 4f_{5/2} regions. The reported binding energies of the metallic Pt(0), Pt(II), and Pt(IV) oxidation states in the Pt 4f_{7/2} region are in the ranges of 71.2-72.0 eV, 72.2-73.0 eV, and 73.2-75.3 eV, respectively. See C. Li, Z. Wang, X. Sui, L. Zhang and D. Gu. Graphitic-C₃N₄ quantum dots modified carbon nanotubes as a novel support material for a low Pt loading fuel cell catalyst. RSC Adv. 6 (2016) 32290-97; N. An, X. Yuan, B. Pan, Q. Li, S. Li and W. Zhang. Design of a highly active Pt/Al₂O₃ catalyst for low temperature CO oxidation. RSC Adv. 4 (2014) 38250-57; C. Dablemont, P. Lang, C. Mangeney, J. Piquemal, V. Petkov, F. Herbst, G. Viau. FTIR and XPS study of Pt nanoparticle functionalization and interaction with alumina. Langmuir 24 (2008) 5832-41; and R. Brandiele, C. Durante, E. Gradzka, G. A. Rizzi, J. Zheng, D. Badocco, P. Centomo, P. Pastore, G. Granozzi and A. Gennaro. One step forward to a scalable synthesis of platinum-yttrium alloyed nanoparticles on mesoporous carbon for oxygen reduction reaction. J. Mater. Chem. A 4 (2016) 12232-12240, each incorporated herein by reference in their entirety. The Pt 4f XPS spectrum of each sample (S2-S6) was deconvoluted into three components, corresponding to the above-mentioned oxidation states of Pt (each component was a doublet composed of Pt 4f_{7/2} and Pt 4f_{5/2} peaks). A representative deconvoluted Pt 4f XPS spectrum of the sample S3 is shown in FIG. 5C. Table 3 summarizes the observed binding energy and the weight of each component in the Pt 4f_{7/2} region for each film. The binding energy position of the Pt (II) overlaps with that of Pt(OH)₂, which could originate from humidity. See V. JohAnek, M. Vaclavu, I. Matolinovi, I. Khalakhan, S. Haviar, V. Matolin. High low-temperature CO oxidation activity of platinum oxide prepared by magnetron sputtering. Applied Surface Science 345 (2015) 319-328, incorporated herein by reference in its entirety. Hence, the remarkable increase of the Pt(0) weight in the annealed samples (S3-S6) could be attributed to the decomposition of Pt(OH)₂ into Pt and PtO (Pt(II)) contained in the as-deposited Pt/SnO₂ film (S2) due to the following reaction: Pt(OH)₂→Pt+PtO+H₂O. Upon further annealing at 300° C. and 450° C., the weights of Pt(0), Pt(II), and Pt(IV) remained unchanged. However, increasing the annealing temperature to 600° C. led to the complete decomposition of Pt(IV) into Pt and PtO. See L. K. Ono, B. Yuan, H. Heinrich, and B. R. Cuenya. Formation and thermal stability of platinum oxides on size-selected platinum nanoparticles: support effects. J. Phys. Chem. C 114 (2010) 22119-22133, incorporated herein by reference in its entirety.

Finally, the O1s XPS spectrum of each sample was resolved into three components centered at lower (O_{I}), intermediate (O_{II}), and higher (O_{III}) binding energies, except that S2 and S6 were resolved into only two components (O_{I} and O_{II}). FIG. 5D shows a representative resolved O1s XPS spectrum for S3. The binding energy value and the weight content of each peak in each film are summarized in Table 3. The reported binding energies of O_{I}, O_{II}, and O_{III} components were in the range 530.5-530.7 eV, 531.5-531.7 eV, and 532.5-532.8 eV, which are assigned to stoichiometric metal-oxide bonds, defects and/or oxygen deficient regions within the lattice, and adsorbed water on the film surface, respectively. See D. Hu, B. Han, R. Han, S. Deng, Y. Wang, Q. Li and Y. Wang. SnO₂ nanorods based sensing material as an isopropanol vapor sensor. New J. Chem., 38(2014) 2443-2450; and L. Cheng, S. Y, T. T. Wang, and J. Luo. Synthesis and enhanced acetone sensing properties of 3D porous flower-like SnO₂ nanostructures. Mater. Lett. 143 (2015) 84-87, each incorporated herein by reference in their entirety.

TABLE 3
XPS characteristics in the Sn 3d_{5/2}, Pt 4f_{7/2}, and O1s of the pristine SnO₂,
the as-deposited Pt/SnO₂, and the annealed Pt/SnO₂ thin films.

| | |
|---|---|
| Peak Binding | |
| Energy (eV) | Weight (%) |

| Sample | Region | Sn (IV) | Sn (II) | Sn (IV) | Sn (II) |
|---|---|---|---|---|---|
| S1 | Sn3d_{5/2} | 487.1 | — | 100 | — |
| S2 | | 486.9 | — | 100 | — |
| S3 | | 486.9 | — | 100 | — |
| S4 | | 487.2 | 485.5 | 94.5 | 5.5 |
| S5 | | 487.0 | 485.3 | 90.7 | 9.3 |
| S6 | | 486.9 | 485.8 | 84.4 | 15.6 |

| | | Peak | | | | | |
|---|---|---|---|---|---|---|---|
| | | Binding Energy (eV) | | | Weight (%) | | |
| Sample | Region | Pt (0) | Pt (II) | Pt (IV) | Pt (0) | Pt (II) | Pt (IV) |
| S2 | Pt4f_{7/2} | 71.5 | 72.6 | 73.3 | 49.4 | 39.3* | 11.3 |
| S3 | | 71.5 | 72.3 | 73.2 | 67.1 | 22.8 | 10.1 |
| S4 | | 71.5 | 72.6 | 73.5 | 67.3 | 21.7 | 11.0 |
| S5 | | 71.6 | 72.7 | 73.4 | 69.4 | 20.8 | 9.8 |
| S6 | | 71.4 | 72.3 | 73.3 | 74.4 | 25.6 | — |

| | | Peak | | | | | |
|---|---|---|---|---|---|---|---|
| | | Binding Energy (eV) | | | Weight (%) | | |
| Sample | Region | O_{I} | O_{II} | O_{III} | O_{I} | O_{II} | O_{III} |
| S1 | O1s | 530.6 | 531.6 | 532.3 | 79 | 13 | 8 |
| S2 | | 530.5 | 531.7 | 532.4 | 80 | 13 | 7 |
| S3 | | 530.3 | 531.5 | — | 84 | 16 | — |
| S4 | | 530.4 | 531.7 | 532.5 | 77 | 21 | 3 |
| S5 | | 530.6 | 531.5 | — | 76 | 24 | — |
| S6 | | 530.5 | 531.6 | 532.3 | 68 | 31 | 1 |

*A mixture of Pt(II) and Pt(OH)₂.

### Example 4

### Gas Sensing Properties

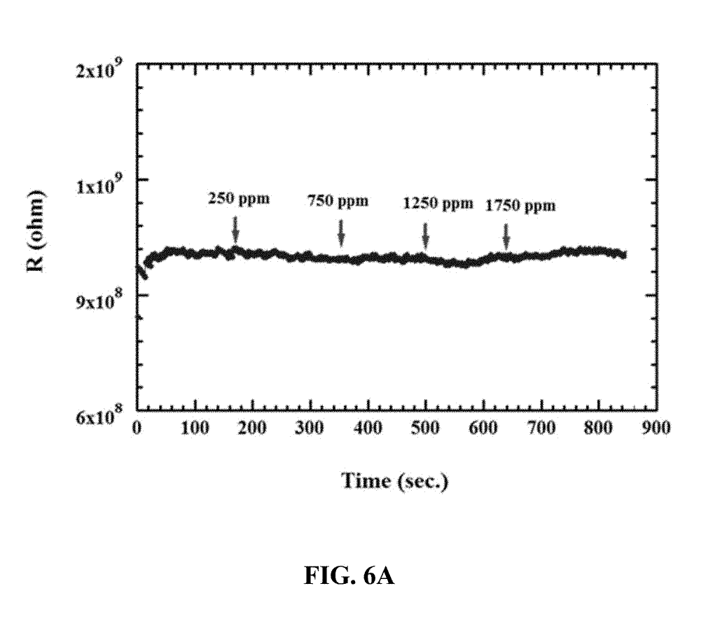

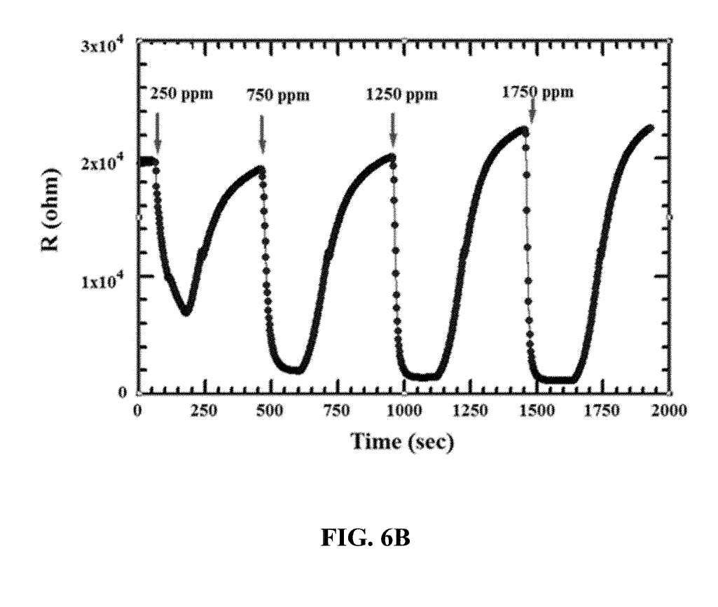

The RT response to various concentrations of H₂ (250, 750, 1250, and 1750 ppm) of sensors S1 and S3, which represent pure SnO₂ and Pt/SnO₂ subjected to post annealing treatment at 150° C., respectively, is shown in respective FIGS. 6A and 6B. As can be observed, the S1 sensor failed to detect H₂ at all H₂ concentrations. This is in concurrence with the literature which claims that pure sputtered SnO₂ films usually work for H₂ detection at temperatures higher than 200° C. See I. H. Kadhim, H. A. Hassan, and Q. N. Abdullah. Hydrogen gas sensor based on nanocrystalline SnO₂ thin film grown on bare Si substrates. Nano-Micro Lett. 8 (2016) 20-28, incorporated herein by reference in its entirety. In contrast, the S3 sensor showed excellent response at RT, and its response amplitudes increased with increasing H₂ concentration. Moreover, it was observed that the electrical resistance of the S3 sensor decreases upon exposure to the H₂ gas and completely returns to its original value upon the removal of H₂ gas, displaying the n-type semiconducting sensing behavior.

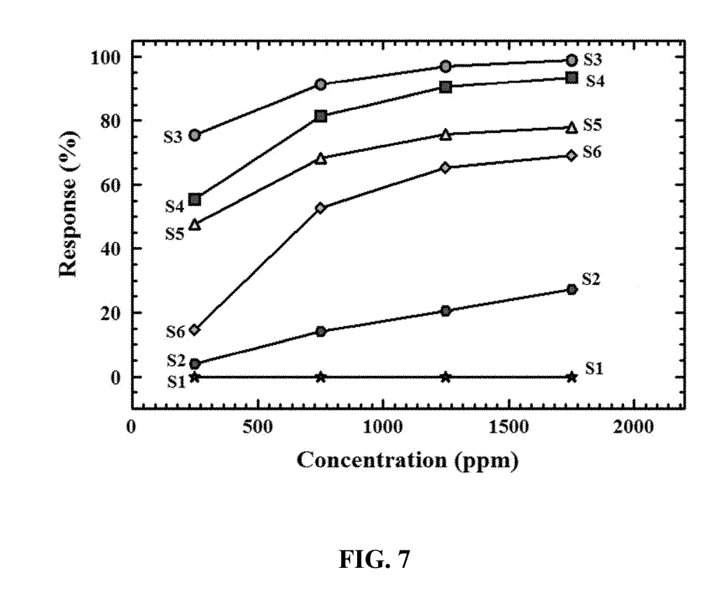

The RT response of the fabricated sensors at different concentrations was studied. FIG. 7 plots the derived sensor responses at RT as a function of H₂ concentrations (250 ppm, 750 ppm, 1250 ppm, and 1750 ppm). As can be noticed, zero-response, low response, and high response were observed for S1 (pure SnO₂), S2 (as deposited Pt/SnO₂), and other sensors (annealed Pt/SnO₂ sensors), respectively. The switch from the zero-response to the low-response is attributed to the chemical and electronic sensitization of the Pt component in the S2 sensor. Moreover, the sensing response of the S2 sensors increases with increasing H₂ concentration from 250 to 1750 ppm. A similar behavior was also observed in other sensors (annealed Pt/SnO₂ sensors). Interestingly, among all annealed sensors, the response of the S3 sensor at all H₂ levels was higher than other sensors followed by S4, S5, and then S6. Compared to the S2 sensor, the S3 sensor exhibited higher response due to the increase in the amount of metallic Pt, resulting from decomposition of Pt(OH)₂ to Pt and PtO as confirmed by XPS analysis. On the other hand, the S3 sensor a showed higher response than the other annealed sensors (S4-S6). This is due to the formation of fully stoichiometric SnO₂ in this sample, as evidenced by XPS results. In addition, the smaller grain size in the S3 sensor could lead to an augmentation of the surface area, which promotes more active sites on the sensor surface, resulting in the enhancement of the gas-sensing performance. It was observed that the increase in the post annealing temperature led to the decrease of the gas response due to the increase of the partial formation of a p-type SnO compound in the S4, S5, and S6 sensors. The formation of SnO was confirmed by XPS analysis of sensors S4, S5, and S6 and by the XRD spectrum of sensor S6. The reason behind the degradation of the sensing signal in these sensors is due to the presence of p-type SnO compound and will be discussed later.

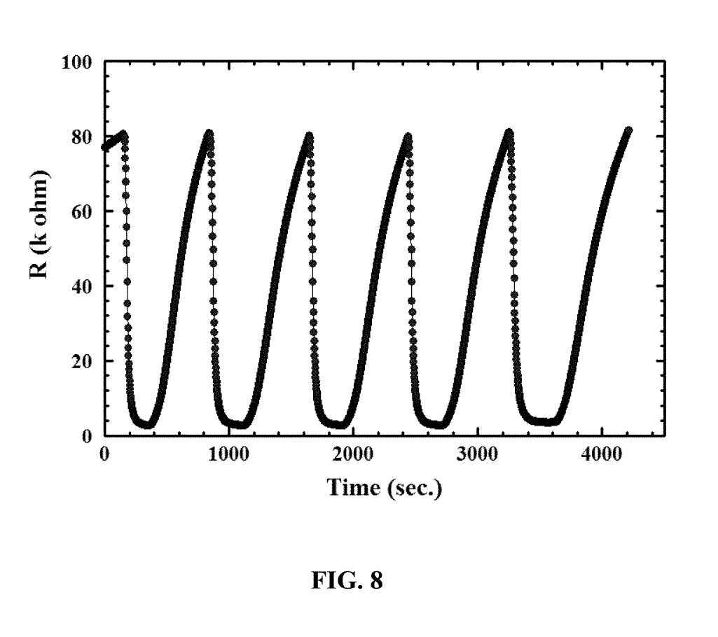

The repeatability of the sensor devices is another important aspect in the evaluation of their suitability. FIG. 8 illustrates the five-cyclic response and recovery curves of the S3 sensor towards 1000 ppm H₂ at RT. As can be observed, the sensor operating at RT was capable of complete recovery upon removal of H₂. The deviation in the response was less than 1%, thus ensuring good repeatability.

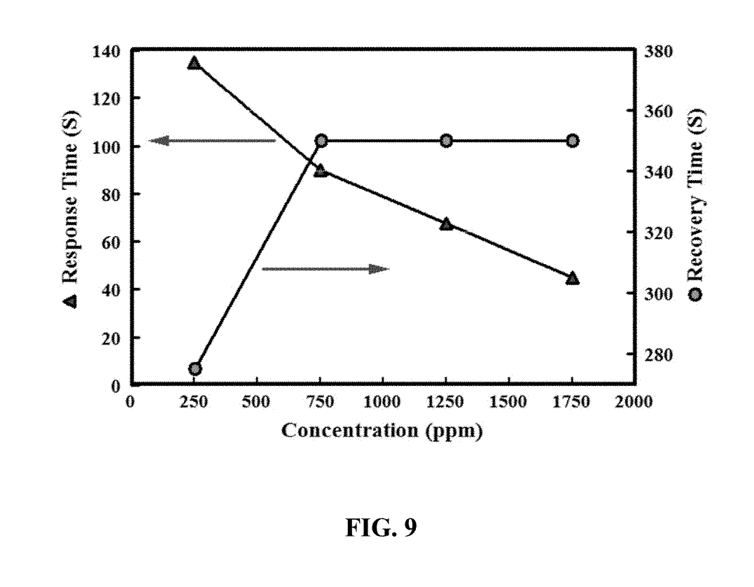

The response time is defined as the time needed by the sensor to attain 90% of its saturation state value, while the recovery time is defined as the time required for the signal to decay by 90%. See S. Basu, Y. Wang, C Ghanshyam and P. Kapur. Fast response time alcohol gas sensor using nanocrystalline F-doped SnO₂ films derived via sol-gel method. Bull. Mater. Sci. 36 (2013)521-33, incorporated herein by reference in its entirety. The gas concentration-dependent recovery and response times of the S3 sensor at RT are shown in FIG. 9. From this figure, it is observed that the response time of the S3 sensor decreases sharply from about 140 s at 250 ppm H₂ to 45 s at 1750 ppm H₂. The decrease of the response time in higher concentrations of H₂ could be attributed to the presence of the large number of H₂ molecules on the sensor surface, which causes more reactions to take place. Therefore, the sensor needs a shorter time to reach equilibrium. See Y. Wang, B. Liu, S. Xiao, H, Li, L. Wang, D. Cai, D. Wang, Y. Liu, Q. Li, T. Wang. High performance and negative temperature coefficient of low temperature hydrogen gas sensors using palladium decorated tungsten oxide. J. Mater. Chem. A 3 (2015) 1317-1324, incorporated herein by reference in its entirety. In contrast, the recovery time was increased from 110 s at 250 ppm to about 140 s at 750 ppm of H₂ and saturated thereafter. This phenomenon could be due to more reactions taking place between residual H₂ captured on the surface of the sensor and sample surface components, which large number of reactions results in long recovery periods. See S. Nasirian, H. Moghaddam. Hydrogen gas sensing based on polyaniline/anatase titania nanocompositc. International Journal of Hydrogen Energy 39 (2014) 630-642, incorporated herein by reference in its entirety.

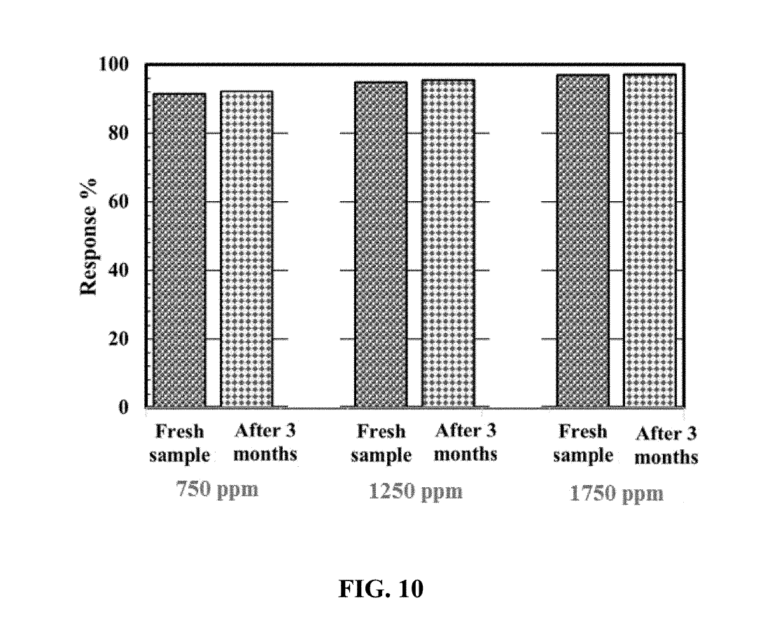

To examine the long-term stability of the S3 sensor fabricated by post annealing treatment (150° C.) of sputtered SnO₂ films catalyzed by an ultra-thin layer of Pt, the gas sensing properties were recorded once again after three months. FIG. 10 displays the response of the S3 sensor exposed at RT to the different concentrations (750, 1250, 1750 ppm) of the H₂ gas. As can be observed, the response of the S3 sensor was stable within a range of 0.7% and no degradation of the sensing signal was recorded over a period of three months verifying a good stability of the fabricated sensor.

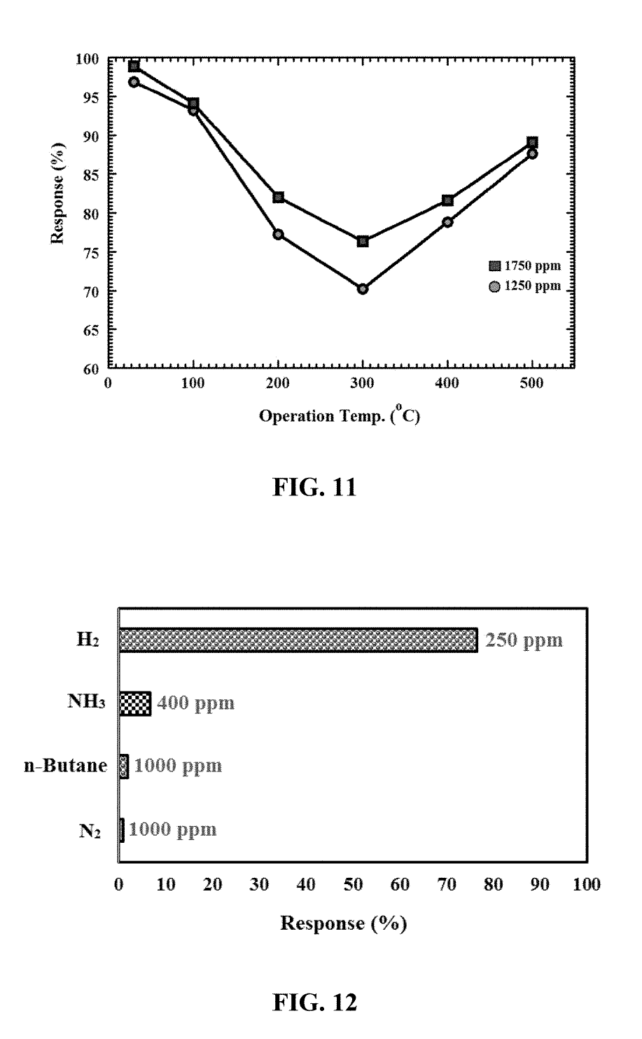

In order to investigate the capability of the sensor to work in high temperature environments, the H₂ sensing performance of the S3 sensor at different operating temperatures ranging from RT to 500° C. was investigated. The responses of the sensor toward 1250 ppm and 1750 ppm of H₂ at different operating temperatures were calculated, and the results are plotted in FIG. 11, which depicts that the sensor exhibits the strongest response at RT (room temperature). At elevated temperatures (100° C.-300° C.), the response value of the sensor declined when sensing the two H₂ concentrations. This is might be due to the formation of relatively fewer active oxygen species on the surface of the sputtered SnO₂ film at that range of temperatures. See W. Zhang, M. Hu, X. Liu, Y. Wei, N. Li, and Y. Qin. Synthesis of the cactus-like silicon nanowires/tungsten oxide nanowires composite for room-temperature NO₂ gas sensor. Journal of Alloys and Compounds 679 (2016) 391-99; Q. A. Drmosh and Z. H. Yamani. Hydrogen sensing properties of sputtered ZnO films decorated with Pt nanoparticles. Ceramics International 42 (2016)12378-84; and I. Kocemba, and J. Rynkowski. The influence of catalytic activity on the response of Pt/SnO₂ gas sensors to carbon monoxide and hydrogen. Sensors and Actuators B 155 (2011) 659-66, each incorporated herein by reference in their entirety.

In the real application, there are different possible interfering gases. Hence, the selectivity, which is defined as the ability of the sensor to identify specific gas among several other gases, is an important factor that needs to be considered in the evaluation of sensor performance. To examine the selectivity of the S3 sensor, the responses to 250 ppm H₂, 400 ppm NH₃, 1000 ppm n-butane, and 1000 N₂ at RT were compared. It is noted that the S3 sensor has a higher response to H₂ than that to other gases (NH₃, n-Butane, and N₂) under the same concentration, indicating that the S3 is much more sensitive and selective to H₂.

The gas sensing properties of the sensors fabricated by this method are compared with the previously demonstrated metal/metal oxide H₂ gas sensors prepared by DC or RF sputtering techniques, as displayed in Table 4. It is clear that the sensors of the present invention have significant advantages over most of the previous work presented in the table. When compared with other sputtered metal/metal oxide H₂ gas sensors, the sensors of the present invention have significant advantages, especially considering their room temperature operating conditions.

TABLE 4
Gas sensing properties of the S3 sensor in comparison with various other
metal/metal oxide sensors fabricated by DC and RF sputtering techniques.

| | | | | | Response | |
|---|---|---|---|---|---|---|
| | | | | | and | |
| | | | | | recovery | |
| | | Operating | Maximum | Concentration | time | |
| Sensor | Fabrication method | Temp. (° C.) | response (S) | (ppm) | (sec.) | Ref. |
| Pt/WO₃ | WO₃ by RF sputtering and Pd | 80 and no | 400⁽²⁾ | 5,000 | NA/NA | * |
| | by DC sputtering | response at 200° C., | | | | |
| | | 250° C., and | | | | |
| | | 300° C. | | | | |
| Micro-sized Pd@SnO₂ + | SnO₂ by DC reactive sputtering | 180 | 3⁽³⁾ | 100 | 50/50 for | ** |
| gamma rays ranging | and Pd by DC sputtering | | | | 50 ppm | |
| from a few mGy up to | | | | | | |
| 100 kGy | | | | | | |
| Pt nanoparticles @ZnO | ZnO by DC reactive sputtering | 300 | 99⁽¹⁾ | 1,200 | 187/834 | *** |
| | and Pd by DC followed by heat | | | | | |
| | treatment | | | | | |
| Au nanopartiules @ZnO | ZnO by DC reactive sputtering | 400 | 60⁽¹⁾ | 600 | 252/639 | † |
| | and Au by DC followed by | | | | | |
| | heat treatment | | | | | |
| Pd decorated MnO₂ | porous alumina was prepared | 300 | 20⁽²⁾ | 100 | 4/35 | †† |
| nanowalls on porous | by electrochemical anodization | | | | | |
| alumina | method, MnO₂ by DC reactive, | | | | | |
| | and Pd by DC sputtering | | | | | |
| Pt-ITO composite | RF sputtering of 0.5 wt. % | 300 | 0.008⁽²⁾ | 1000 | 5/NA | ‡ |
| | Pd-catalyzed ITO targets | | | | | |
| Heated Pt/SnO₂ | SnO₂ by RF sputtering and Pd | RT | 97⁽¹⁾ | 1,250 | 67/350 | This |
| | by DC sputtering followed by | | | | | work |
| | heat treatment @ 150° C. | | | | | |

(1): S=[(R₀−R_{g})/R₀*100]; (2): S=R₀/R_{g}; (3): S=V_{g}/V₀; and (4): S=(I₀−I_{g})/I₀, where R, V, and I are the electrical resistance, potential, and current, respectively. The subscripts “0” and “g” refer to the electrical parameter of the sensor when exposed to air, or to H₂, respectively. References: * S. J. Ippolito, S. K. Kandasamy, K. Kalantar, W. Wlodarski. Hydrogen sensing characteristics of WO₃ thin film conductometric sensors activated by Pt and Au catalysts. Sensors and Actuators B 108 (2005) 154-158; **N. V. Duy et al.; *** Q. A. Drmosh and Z. H. Yamani. Hydrogen sensing properties of sputtered ZnO films decorated with Pt nanoparticles. Ceramics International 42 (2016)12378-84.; Q. A. Drmosh, and Z. H. Yamani. Synthesis characterization, and hydrogen gas sensing properties of AuNs-catalyzed ZnO sputtered thin films. Applied Surface Science 375 (2016)57-64^{†}; ^{††} A. Sanger, A. Kumar, A. Kumar, R. Chandra. Highly sensitive and selective hydrogen gas sensor using sputtered grown Pd decorated MnO₂ nanowalls. Sensors and Actuators B 234 (2016) 8-14; ^{‡} and C. Ling, Q. Xue, Z. Han, H. Lu, F. Xia, Z. Yan, L. Deng. Room temperature hydrogen sensor with ultrahigh-responsive characteristics based on Pd/SnO₂/SiO₂/Si heterojunctions. Sensors and Actuators B 227 (2016) 438-447, each incorporated herein by reference in their entirety.

1: A room temperature hydrogen gas sensor, comprising:
at least two electrodes on a substrate, the electrodes separated by 10-500 μm;
a SnO₂ layer in contact with the at least two electrodes on the substrate, the SnO₂ layer having an average thickness of 10-700 nm; and
a platinum layer in contact with the SnO₂ layer, the platinum layer having an average thickness of 1-15 nm.

2: The hydrogen gas sensor of claim 1, wherein the SnO₂ layer consists essentially of SnO₂, and the Pt layer consists essentially of Pt.

3: The hydrogen gas sensor of claim 1, wherein the at least two electrodes are substantially planar.

4: The room temperature hydrogen gas sensor of claim 1, wherein the platinum layer has an RMS surface roughness of 0.1-4 nm.

5: The room temperature hydrogen gas sensor of claim 1, wherein the substrate comprises silica.

6: The room temperature hydrogen gas sensor of claim 5, having a transmittance of 30-50% for a wavelength in a range of 420-500 nm.

7: The hydrogen gas sensor of claim 1, wherein the SnO₂ layer comprises polycrystalline SnO₂ having an average grain size of 5-20 nm.

8: A method of making the hydrogen gas sensor of claim 1, comprising:
sputtering SnO₂ onto the at least two electrodes on the substrate to produce an amorphous SnO₂ layer,
sputtering platinum onto the amorphous SnO₂ layer to produce a deposited platinum layer; and
annealing the amorphous SnO₂ layer and the deposited platinum layer at 130-250° C.

9: The method of claim 8, wherein the annealing is at 140-170° C. for 1-5 hours.

10: The method of claim 8, wherein the SnO₂ is sputtered by a RF sputtering mode, and the Pt is sputtered by a DC sputtering mode.

11: A method of using the room temperature hydrogen gas sensor of claim 1, comprising:
contacting the platinum layer with a first gas sample comprising hydrogen gas, and
measuring a first resistivity across the at least two electrodes, wherein the first resistivity is decreased by 70-99.9% relative to a second resistivity arising from a second gas sample, the second gas sample substantially free of hydrogen gas.

12: The method of claim 11, wherein the first gas sample comprises 50-1800 ppm hydrogen gas.

13: The method of claim 11, wherein the first gas sample has a temperature of 0-50° C. and a pressure of 0.9-1.1 atm.

14: The method of claim 13, wherein the first gas sample has a temperature of 20-35° C.

15: The method of claim 11, wherein the second gas sample comprises 300-5,000 ppm of at least one gas selected from the group consisting of NH₃, n-butane, O₂, CO₂, and N₂.

16: The method of claim 11, wherein the decrease in the first resistivity has a response time of 0.5-100 s.

17: The method of claim 11, wherein the second gas sample comprises 0.1-99 vol % of at least one gas selected from the group consisting of O₂, CO₂, H₂O, Ar and N₂, relative to a total volume of the second gas sample, or consists essentially of O₂, CO₂, H₂O, Ar and/or N₂.

18: The method of claim 11, wherein the decrease in the first resistivity has a recovery time of 200-400 s.

19: The method of claim 11, wherein the room temperature hydrogen gas sensor is in contact with 500-5,000 ppm H₂ gas for 1-6 months before the contacting with the first gas sample.

20: The method of claim 11, which has a repeatability of at least 99%.
